(19) United States
(12) Patent Application Publication
(10) Pub. No.: US 2026/0059955 A1
(43) Pub. Date: Feb. 26, 2026

(54) DISPLAY DEVICE AND DISPLAY PANEL

(71) Applicant: LG Display Co., Ltd., Seoul (KR)

(72) Inventors: Yu Cheol YANG, Paju-si (KR); Seung Han PAEK, Paju-si (KR); Kyung Jae YOON, Paju-si (KR); Jeon Phill HAN, Paju-si (KR); Nam Woo KIM, Paju-si (KR)

(73) Assignee: LG Display Co., Ltd., Seoul (KR)

(21) Appl. No.: 19/285,427

(22) Filed: Jul. 30, 2025

(30) Foreign Application Priority Data
Aug. 26, 2024 (KR) 10-2024-0113985

(51) Int. Cl. H10K 59/127; H10K 59/131; H10K 59/80

(52) U.S. Cl. CPC H10K 59/1275; H10K 59/131; H10K 59/871

(57) ABSTRACT

Disclosed are a display device and a display panel. The display device includes a substrate including a first substrate and a second substrate spaced apart from each other, a support member arranged between the first substrate and the second substrate, a circuit layer arranged on the first substrate, a light-emitting element layer arranged on the circuit layer, and a connection wire arranged on the support member. An edge of the support member overlaps the first substrate and the second substrate in a first direction along a thickness direction of the substrate.

### CROSS-REFERENCE TO RELATED APPLICATION

This application claims priority and the benefit of Korean Patent Application No. 10-2024-0113985, filed Aug. 26, 2024, the entire contents of which are hereby expressly incorporated for all purposes.

### BACKGROUND

### Technical Field

The present disclosure relates to a display panel, and more specifically, for example, without limitation, to a display panel structurally improved to prevent damage caused by an etching process, and a display device including the same.

### Description of Related Art

A flexible display may change a screen size by rolling, folding, or bending a flexible panel. The flexible display may be implemented as a rollable display, a foldable display, a bendable display, a slidable display, etc. Such a flexible display may be applied not only to mobile devices such as smartphones and tablet PCs, but also to televisions, vehicle displays, wearable devices, etc., and their application fields are expanding.

The flexible display may implement a bezel bended display with a minimized bezel area by folding a non-display area using a flexible panel structure.

The description provided in the description of the related art section should not be assumed to be prior art merely because it is mentioned in or associated with the description of the related art section. The description of the related art section may include information that describes one or more aspects of the subject technology, and the description in this section does not limit the disclosure.

### BRIEF SUMMARY

The inventor has realized that in the related art, a structure of a display panel may be easily damaged during an etching process. Accordingly, an exemplary embodiment of the present disclosure provides a display panel including a substrate to which a double-sided etching process is applied for manufacturing process optimization, and a display device including the same.

An exemplary embodiment of the present disclosure provides a display panel structurally improved to prevent damage caused by an etching process, and a display device including the same.

An exemplary embodiment of the present disclosure provides a display device including a narrow bezel by applying a structurally improved substrate to a pad portion and bending the substrate.

The objectives to be solved by the exemplary embodiments of this disclosure are not limited to the objectives mentioned above, and other objectives not mentioned will be clearly understood by those skilled in the art from the following descriptions.

A display device according to one exemplary embodiment of the present disclosure includes a display panel and a circuit board connected to a pad portion of the display panel, and the display panel includes: a substrate including a first substrate and a second substrate spaced apart from each other; a support member arranged between the first substrate and the second substrate; a circuit layer arranged on the first substrate; a light-emitting element layer arranged on the circuit layer; and a connection wire arranged on the support member, wherein an edge of the support member overlaps the first substrate and the second substrate.

A display panel according to one exemplary embodiment of the present disclosure includes: a substrate including a first substrate and a second substrate spaced apart from each other; a support member arranged between the first substrate and the second substrate; a circuit layer arranged on the first substrate; a light-emitting element layer arranged on the circuit layer; and a connection wire arranged on the support member, wherein an edge of the support member overlaps the first substrate and the second substrate.

In addition, the support member may include a protrusion that protrudes further than a lower surface of the substrate.

According to the present disclosure, process optimization may be implemented by partially etching one surface of a substrate and etching the entire other surface of the substrate, which is an opposite surface of the one surface, through an etching process. For example, a manufacturing process may be simplified by performing the etching process on a plurality of display panels arranged on a mother substrate. Therefore, the productivity of the display device may be improved. The plurality of display panels arranged on the mother substrate may be individually separated by a cutting process.

According to the present disclosure, a substrate made of a glass material is processed through an etching process, so that the rigidity of the substrate may be maintained.

According to the present disclosure, a protective layer is formed on a substrate made of a glass material and having a bending area, so that damage to a connection wire arranged in the bending area may be prevented during an etching process of the substrate.

Various useful advantages and effects of the exemplary embodiments of this disclosure are not limited to the above-described contents, and effects which are not described above will be clearly understood by those skilled in the art from the following descriptions.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a plan view showing a display panel according to one exemplary embodiment of the present disclosure;

FIG. 2A is a cross-sectional view showing a pixel area of a display panel according to one exemplary embodiment of the present disclosure;

FIG. 2B is an enlarged view showing an area A in FIG. 2A;

FIG. 3 is a perspective view showing a display device according to one exemplary embodiment of the present disclosure;

FIG. 4 is a cross-sectional view taken along line I-I′ in FIG. 3;

FIG. 5 is an enlarged view showing an area B in FIG. 4;

FIG. 6 is a perspective view showing a bent appearance of a display device according to one exemplary embodiment of the present disclosure;

FIG. 7 is a cross-sectional view taken along line II-II′ in FIG. 6;

FIG. 8 is a view showing a neutral plane according to bending;

FIG. 9A, FIG. 9B, FIG. 9C, FIG. 9D, FIG. 9E and FIG. 9F are views showing a manufacturing process of a display panel according to one exemplary embodiment of the present disclosure;

FIG. 10 is a perspective view showing a bent appearance of a display device according to another exemplary embodiment of the present disclosure;

FIG. 11 is a cross-sectional view taken along line III-III′ in FIG. 10;

FIG. 12 is a view showing a display device according to another exemplary embodiment of the present disclosure based on an area B in FIG. 4;

FIG. 13A, FIG. 13B, FIG. 13C, FIG. 13D, FIG. 13E and FIG. 13F are views showing a manufacturing process of a display panel according to another exemplary embodiment of the present disclosure;

FIG. 14 is a perspective view showing a bent appearance of a display device according to another exemplary embodiment of the present disclosure;

FIG. 15 is a cross-sectional view taken along line IV-IV′ in FIG. 14;

FIG. 16 is a view showing a display device according to another exemplary embodiment of the present disclosure based on an area B in FIG. 4;

FIG. 17 is a perspective view showing a bent appearance of a display device according to another exemplary embodiment of the present disclosure;

FIG. 18 is a cross-sectional view taken along line V-V′ in FIG. 17; and

FIG. 19 is a view showing a display device according to another exemplary embodiment of the present disclosure based on an area B in FIG. 4.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The scope of the claims is not limited by the disclosure.

Shapes, sizes, dimensions (e.g., length, width, height, thickness, radius, diameter, area, etc.), ratios, angles, numbers, and the like disclosed in the drawings for describing the embodiments of the present disclosure are exemplary, and the present disclosure is not limited to the illustrated items. Like reference numerals refer to like elements throughout. In addition, in describing the present disclosure, if it is determined that the detailed description of the related known technology may unnecessarily obscure the subject matter of the present disclosure, the detailed description thereof will be omitted.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terms such as “include,” “have,” “comprise,” “contain,” “constitute,” “make up of,” “formed of,” and “consist of” used herein are generally intended to allow other components to be added unless the terms are used with the term “only”. References to the singular shall be construed to include the plural unless expressly stated otherwise.

In interpreting a component, it is interpreted to include an error range even if there is no separate description.

When describing a positional or interconnected relationship between two components, such as “on”, “above”, “over”, “below”, “under”, “beside”, “beneath”, “near”, “close to,” “adjacent to”, “on a side of”, “next”, “connect or couple with”, “crossing”, “intersecting”, etc., one or more other components may be interposed between them unless “immediately” or “directly” is used.

It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

When describing a temporal contextual relationship is described, such as “after”, “following”, “next to” or “before”, it may not be continuous on a time scale unless “immediately” or “directly” is used.

The terms “first”, “second” and the like may be used to distinguish components from each other, but the functions or structures of the components are not limited by ordinal numbers or component names in front of the components.

The term “at least one” should be understood as including all possible combinations which can be suggested from one or more relevant items. For example, the meaning of “at least one of a first item, a second item, or a third item” may be each one of the first item, the second item, or the third item and also be all possible combinations that can be suggested from two or more of the first item, the second item, and the third item.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

The following embodiments may be combined or associated with each other in whole or in part, and various types of interlocking and driving are technically possible. The embodiments may be implemented independently of each other or together in an interrelated relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

Throughout the disclosure, the same reference numerals refer to the same component.

A display device according to an embodiment in this disclosure may include a display device itself in a narrow sense, an application product including a display in a narrow sense, or even a set device that is an end-consumer device.

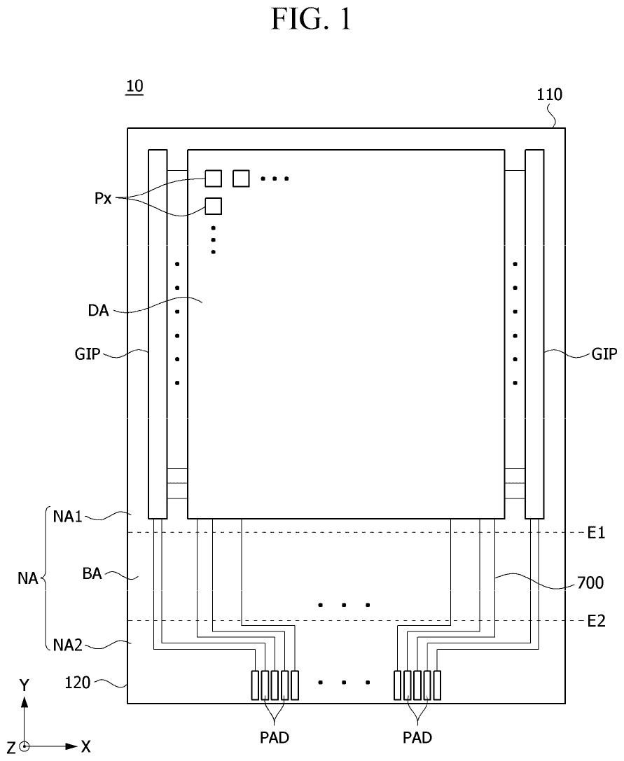

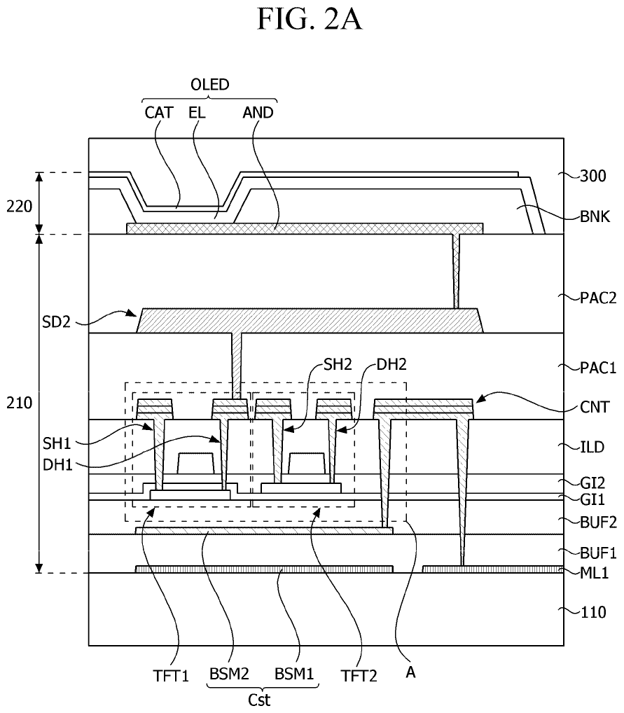

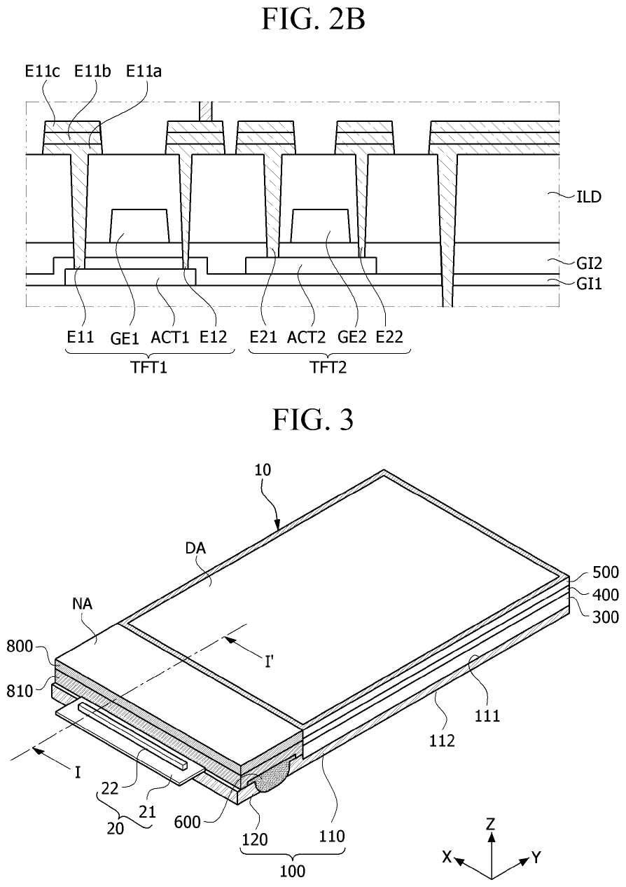

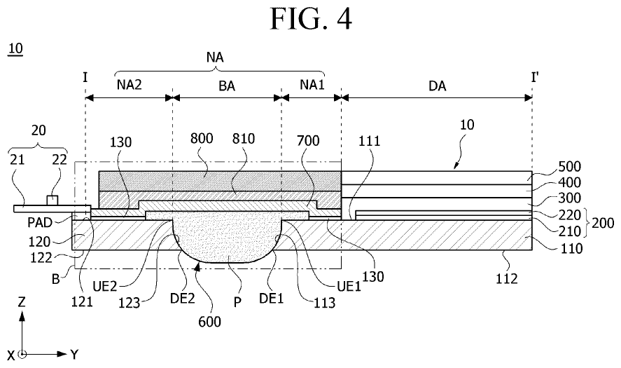

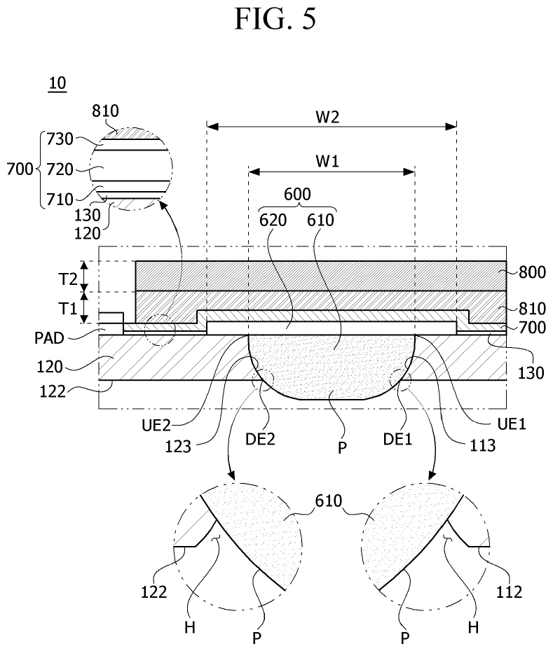

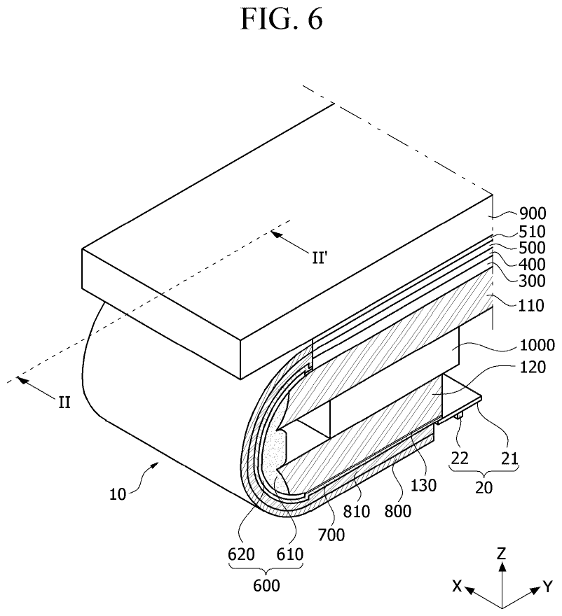

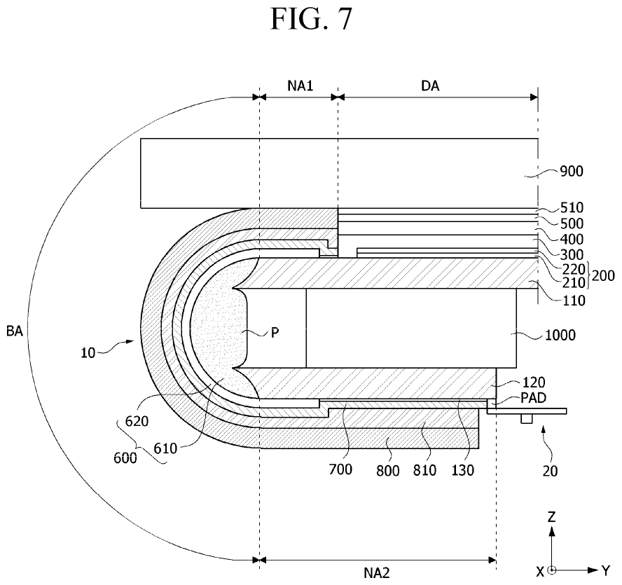

FIG. 1 is a plan view showing a display panel according to one exemplary embodiment of the present disclosure. FIG. 2A is a cross-sectional view showing a pixel area of the display panel according to one exemplary embodiment of the present disclosure. FIG. 2B is an enlarged view showing an area A in FIG. 2A. FIG. 3 is a perspective view showing a display device according to one exemplary embodiment of the present disclosure. FIG. 4 is a cross-sectional view taken along line I-I′ in FIG. 3. FIG. 5 is an enlarged view showing an area B in FIG. 4. FIG. 6 is a perspective view showing a bent appearance of the display device according to one exemplary embodiment of the present disclosure, and FIG. 7 is a cross-sectional view taken along line II-II′ in FIG. 6.

Referring to FIGS. 1 to 7, the display device according to one exemplary embodiment of the present disclosure may include a display panel 10 and a circuit board 20 connected to a pad portion PAD of the display panel 10. In addition, an input image may be visually reproduced on the display panel 10.

The display panel 10 may include a display area DA where an image is displayed and a non-display area NA where no image is displayed. The non-display area NA may be placed outside the display area AA. For example, the non-display area NA may be an area adjacent to the display area DA. Further, the non-display area NA may be an area disposed adjacent to the display area AA and configured to surround the display area DA. The display panel 10 may be a panel having a rectangular structure having a width in an X-axis direction, a length in a Y-axis direction, and a thickness in a Z-axis direction. In such a case, the width and length of the display panel 10 may be set to various design values depending on the application field of the display device. The X-axis direction may mean a width direction, a row direction, or a horizontal direction, the Y-axis direction may mean a length direction, a column direction, or a vertical direction, and the Z-axis direction may mean an up-down direction, a vertical direction, or a thickness direction. The X-axis direction, the Y-axis direction, and the Z-axis direction may be perpendicular to one another, but may also mean different directions not perpendicular to one another. Therefore, each of the X-axis direction, the Y-axis direction, and the Z-axis direction may be described as any one of a first direction, a second direction, and a third direction. A plane extended in the X-axis direction and the Y-axis direction may mean a horizontal plane.

In the display area DA of the display panel 10, data lines, gate lines crossing the data lines, and pixels Px arranged in a matrix form defined by the data lines and the gate lines may be disposed.

Each of the plurality of subpixels Px is a minimum unit which configures the display area and n subpixels form one pixel. Each of the plurality of subpixels may emit light having different wavelengths from each other. The plurality of subpixels may include first to third subpixels which emit different color light from each other. For example, the sub-pixels may include red, green, and blue sub-pixels. Meanwhile, the sub-pixels may also include white sub-pixel. The plurality of subpixels may be variously modified in colors and configurations, as necessary. However, the present disclosure is not limited thereto.

For example, the plurality of subpixels may include red, green, and blue subpixels, in which the red, green, and blue subpixels may be disposed in a repeated manner. Alternatively, the plurality of subpixels may include red, green, blue, and white subpixels, in which the red, green, blue, and white subpixels may be disposed in a repeated manner, or the red, green, blue, and white subpixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the subpixels are not limiting, and may be configured in various forms according to light-emitting characteristics, device lifespans, and device specifications.

Meanwhile, the subpixels may have different light-emitting areas according to light-emitting characteristics. For example, a subpixel that emits light of a color different from that of a blue subpixel may have a different light-emitting area from that of the blue subpixel. For example, the red subpixel, the blue subpixel, and the green subpixel, or the red subpixel, the blue subpixel, the white subpixel, and the green subpixel may each has a different light-emitting area.

A pixel Px may include a plurality of light-emitting elements. In addition, the light-emitting elements may be implemented in an element structure such as organic light-emitting diode (OLED) display, quantum dot display, and micro light-emitting diode (micro LED) display. In the following description, the light-emitting elements will be described as an OLED structure including an organic compound layer.

A host system transmits pixel data of an input image to a drive IC. The host system may be connected to the drive IC through the circuit board 20.

In the non-display area NA, various wires and driving circuits may be arranged and the pad portion PAD to which an integrated circuit, a printed circuit, etc., are connected may be arranged.

The circuit board 20 may be a flexible printed circuit board, and may be connected to the drive IC through the pad portion PAD. The drive IC may be arranged on the display panel 10, but is not necessarily limited thereto. For example, the drive IC may also be arranged on the circuit board 20.

The circuit board 20 may include a substrate body 21 and a drive IC 22 arranged on the substrate body 21. The substrate body 21 may be a flexible circuit film, and may be attached to one side of a second substrate 120 through a film attachment process. For example, the substrate body 21 may include a flexible polymer film. For example, the flexible polymer film may be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto.

For example, the drive IC may be a data driving IC and/or a gate driving IC, but the exemplary embodiments of the present disclosure are not limited thereto. Lines through which control signals for controlling the drive IC are supplied may be disposed on the display panel. For example, the control signals may include various timing signals including a clock signal, an input data enable signal, and a synchronization signal (for example, a horizontal synchronization signal and a vertical synchronization signal), but the exemplary embodiments of the present disclosure are not limited thereto. Here, the horizontal synchronization signal is a signal representing a time taken to display one horizontal line of a screen and the vertical synchronization signal is a signal representing a time taken to display a screen of one frame. The input data enable signal may correspond to a signal indicating a period for which a data voltage is supplied to the pixel.

The non-display area NA may include a first non-display area NA1, a bending area BA, and a second non-display area NA2.

The first non-display area NA1 may be an area surrounding at least a part of the display area DA.

The bending area BA is an area adjacent to at least one of the plurality of sides of the first non-display area NA1 and may be a bendable area.

The second non-display area NA2 is an area adjacent to at least one of a plurality of sides of the bending area BA, and the pad portion PAD may be arranged in the second non-display area NA2. For example, the bending area BA may be in a bent state from a flat state, and the remaining area of a substrate 100 excluding the bending area BA may be in a flat state. As the bending area BA is bent, the second non-display area NA2 may be positioned on a back surface of the display area DA to overlap it. The pad portion PAD may be a pad electrode.

That is, the bending area BA is positioned between the first non-display area NA1 and the second non-display area NA2, and various structures such as organic layers, inorganic layers, and wires arranged in the bending area BA may be bent.

A plurality of connection wires 700 may extend from a plurality of pad portions PAD of the second non-display area NA2 toward the bending area BA and the first non-display area NA1, and may be electrically connected to wires of the display area DA. Here, the connection wire 700 may be referred to as a link line. Therefore, a plurality of light-emitting elements OLEDs may be driven by receiving signals from one or more circuit boards 20 through the wires of the display area DA and the connection wires 700 of the non-display area NA. For example, the wires of the display area DA may be wires for transmitting signals output from the circuit board 20 to the plurality of light-emitting elements OLEDs together with the plurality of connection wires 700. The wires of the display area DA may include a plurality of data lines, a plurality of gate lines, etc., and may be electrically connected to the plurality of light-emitting elements OLEDs, respectively. The wires of the display area DA may extend from the display area DA toward the non-display area NA and be electrically connected to the plurality of connection wires 700. Accordingly, the signals output from the circuit board 20 may be transmitted to each of the plurality of light-emitting elements OLEDs through the plurality of connection wires 700 and the wires of the display area DA.

As the bending area BA is bent, a part of the plurality of connection wires 700 may also be bent accordingly. Stress may be concentrated on a part of the bent connection wire 700, and thus cracks may occur in the connection wire 700. Therefore, the plurality of connection wires 700 may each be made of a conductive material having excellent ductility in order to reduce cracks during bending of the bending area BA. For example, the plurality of connection wires 700 may each be made of a conductive material having excellent ductility, such as gold (Au), silver (Ag), and aluminum (Al); however, the exemplary embodiments of the present disclosure are not limited thereto. In addition, the plurality of connection wires 700 may each be made of one of various conductive materials used in the display area DA. For example, the plurality of connection wires 700 may each be made of molybdenum (Mo), chromium (Cr), titanium (Ti), nickel (Ni), neodymium (Nd), copper (Cu), and an alloy of silver (Ag) and magnesium (Mg), or a combination thereof; however, exemplary embodiments of the present disclosure are not limited thereto. In addition, the plurality of connection wires 700 may be configured in a multilayer structure including various conductive materials. For example, the plurality of connection wires 700 may be configured in a triple layer structure of titanium (Ti)/aluminum (Al)/titanium (Ti). For example, the plurality of connection wires 700 may be formed in a triple layer structure such as first source and drain electrodes E11 and E12 and second source and drain electrodes E21 and E22 arranged in the display area DA. Therefore, the plurality of connection wires 700 may be simultaneously formed with the first source and drain electrodes E11 and E12 and the second source and drain electrodes E21 and E22 in a single mask process.

That is, the plurality of connection wires 700 may be formed in the same material and/or the same structure as the source electrode or the drain electrode arranged in the display area DA.

The plurality of connection wires 700 may be configured in various shapes in order to reduce stress. At least a part of the plurality of connection wires 700 arranged on the bending area BA may also extend in the same direction as the extension direction of the bending area BA, or may extend in a direction different from the extension direction of the bending area BA to reduce stress. For example, when the bending area BA extends in one direction from the first non-display area NA1 toward the second non-display area NA2, at least a part of the connection wires 700 arranged on the bending area BA may extend in a direction inclined with respect to the one direction. In addition, at least a part of the plurality of connection wires 700 may be configured as a pattern of various shapes. For example, at least a part of the plurality of connection wires 700 arranged on the bending area BA may also have a shape in which conductive patterns having at least one shape among a diamond shape, a rhombus shape, a trapezoidal wave shape, a triangular wave shape, a sawtooth wave shape, a sine wave shape, a circular shape, and an omega (Ω) shape are repeatedly arranged; however, exemplary embodiments of the present disclosure are not limited thereto. Accordingly, in order to minimize stress concentrated on the plurality of connection wires 700 and cracks caused by the stress, the shapes of the plurality of connection wires 700 may be formed in various shapes including the shapes described above; however, exemplary embodiments of the present disclosure are not limited thereto.

The display panel 10 may be manufactured based on a flexible plastic material such as polyimide or a flexible glass substrate having a thin thickness. For example, the substrate 100 of the display panel 10 may be made of a glass material in consideration of a double-sided etching process.

Referring to FIGS. 2A and 2B, a first transistor TFT1 and a second transistor TFT2 may be arranged on a first substrate 110 of the substrate 100 in the display area DA, and a light-emitting element OLED may be arranged on a planarization layer PAC2. The first transistor TFT1 and the second transistor TFT2 may be implemented as a thin film transistor (TFT).

Active layers of the thin-film transistors TFTs may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

Herein, the display area DA is implemented, by way of example, with light-emitting elements OLED used for an organic light-emitting display device, but is not necessarily limited thereto. For example, the display area DA may be implemented with any one of LCD, QLED, and Micro LED.

A first light shield layer BSM1 and a first metal layer MLI may be arranged on the first substrate 110 of the substrate 100.

The first light shield layer BSM1 may include molybdenum and/or aluminum. The first light shield layer BSM1 may block light incident to the first semiconductor layer ACT1 or the second semiconductor layer ACT2. Here, the first light shield layer BSM1 may overlap the first semiconductor layer ACT1 or the second semiconductor layer ACT2 in the Z direction.

The first metal layer MLI may be disposed to be spaced apart from the first light shield layer BSM1 and may be formed together with the first light shield layer BSM1 in a process of forming the first light shield layer BSM1. Additionally, the first metal layer MLI may be electrically connected to the third pad layer 143 of the pad part PAD.

The multi-buffer layer BUF1 may delay the diffusion of moisture or oxygen that has penetrated the substrate 100, and may be formed by alternately stacking silicon nitride (SiNx) and silicon oxide (SiOx) at least once. For example, the multi-buffer layer BUF1 may be formed by inorganic film in multiple layers, for example, inorganic films in multiple layers may formed by alternately stacking one or more silicon oxide (SiOx) films, one or more silicon nitride (SiNx) films, and one or more amorphous silicon (a-Si), but the exemplary embodiments of the present disclosure are not limited thereto. The multi-buffer layer BUF1 may be excluded or a single buffer layer formed of an inorganic film of single layer may be provided in accordance with the structure or properties of the display device, for example, the inorganic film in a single layer may be a silicon oxide (SiOx) film or a silicon nitride (SiNx) film. However, the exemplary embodiments of the present disclosure are not limited thereto.

A second light shield layer BSM2 may be disposed on the multi-buffer layer BUF1. The second light shield layer BSM2 may include molybdenum and/or aluminum. The second light shield layer BSM2 may block light incident to the first semiconductor layer ACT1 or the second semiconductor layer ACT2. The second light shield layer BSM2 may be disposed to overlap the first light shield layer BSM1 in the Z direction, more effectively blocking light incident to the first semiconductor layer ACT1 or the second semiconductor layer ACT2.

The active buffer layer BUF2 may protect the first semiconductor layer ACT1 and may serve to block various types of defects coming from the substrate 100. Here, the active buffer layer BUF2 may be made of a-Si, silicon nitride (SiNx), or silicon oxide (SiOx).

The first semiconductor layer ACT1 of the first transistor TFT1 may be made of a polycrystalline semiconductor layer, and the first semiconductor layer ACT1 may include a channel region, a source region, and a drain region.

A first gate electrode GE1 may be disposed on the upper gate insulating layer GI2 so as to overlap the first semiconductor layer ACT1. Here, the upper gate insulating layer GI2 may be disposed on a lower gate insulating layer GI1.

The second transistor TFT2 may be disposed on the lower gate insulating layer GI1. An upper gate insulating layer GI2 may be disposed on the second semiconductor layer ACT2 to insulate the second gate electrode GE2 from the second semiconductor layer ACT2.

An interlayer insulating layer ILD may be disposed on the first gate electrode GE1 and the second gate electrode GE2. The first gate electrode GE1 and the second gate electrode GE2 may be a single layer or a multilayer made of any one of molybdenum (Mo), aluminum (Al), chromium (Cr), gold (Au), titanium (Ti), nickel (Ni), neodymium (Nd), and copper (Cu), or an alloy thereof, but without being limited thereto.

After the interlayer insulating layer ILD is disposed, a first source contact hole SH1 and a first drain contact hole DH1 may be formed respectively in correspondence to the source region and drain region of the first transistor TFT1, and a second source contact hole SH2 and a second drain contact hole DH2 may be formed respectively in correspondence to the source region and drain region of the second transistor TFT2.

The first source contact hole SH1 and the first drain contact hole DH1 may be a hole formed continuously from the interlayer insulating layer ILD to the lower gate insulating layer GI1, and the second source contact hole SH2 and the second drain contact hole DH2 may also be formed continuously from the interlayer insulating layer ILD to the upper gate insulating layer GI2 in the second transistor TFT2.

The first source electrode E11 and the first drain electrode E12 corresponding to the first transistor TFT1, and the second source electrode E21 and the second drain electrode E22 corresponding to the second transistor TFT2 may be formed simultaneously. Thereby, the number of processes for forming the source and drain electrodes of each of the first transistor TFT1 and the second transistor TFT2 may be reduced.

The first source and drain electrodes E11 and E12 and the second source and drain electrodes E21 and E22 may be a single layer or a multilayer made of any one of molybdenum (Mo), aluminum (Al), chromium (Cr), gold (Au), titanium (Ti), nickel (Ni), neodymium (Nd), and copper (Cu), or an alloy thereof, but without being limited thereto.

The first source and drain electrodes E11 and E12 and the second source and drain electrodes E21 and E22 may be made of a stacked structure, and in the present disclosure, may be made of a three-layer structure. For example, the first source electrode E11 may be composed of a first layer E11a made of Ti, a second layer E11b made of Al, and a third layer E11c made of Ti, and the other source and drain electrodes may have the same structure.

A storage capacitor Cst may be disposed between the first transistor TFT1 and the second transistor TFT2. According to an exemplary embodiment, the storage capacitor Cst may be formed using the first light shield layer BSM1 and second light shield layer BSM2. For example, the second light shield layer BSM2 may be electrically connected to the pixel circuit through a storage supply line CNT. However, the structure of the storage capacitor Cst is not necessarily limited to this and may be formed in various forms by using two different metal layers.

The storage supply line CNT may be made of the same material as, on the same plane as, the first source and drain electrodes E11 and E12 and the second source and drain electrodes E21 and E22, and thus the storage supply line CNT may be formed simultaneously with the first source and drain electrodes E11 and E12 and the second source and drain electrodes E21 and E22 by using the same mask process.

A first planarization layer PAC1 may be formed on the first source and drain electrodes E11 and E12, the second source and drain electrodes E21 and E22, and the storage supply line CNT. Specifically, the first planarization layer PAC1 may be disposed by applying a full coating of an organic insulating material such as acrylic resin on the first source and drain electrodes E11 and E12, the second source and drain electrodes E21 and E22, and the storage supply line CNT.

After disposing the first planarization layer PAC1, a contact hole may be formed through a photolithography process to expose the first source electrode E11 or first drain electrode E12 of the first transistor TFT1. A connection electrode SD2 may be disposed in the contact hole region exposing the first drain electrode E12 by using a material made of Mo, Ti, Cu, AlNd, Al, Cr, or an alloy thereof.

A second planarization layer PAC2 may be disposed on the connection electrode SD2. Then, a contact hole exposing the connection electrode SD2 may be formed in the second planarization layer PAC2 to dispose a light-emitting element OLED connected to the first transistor TFT1. The connection electrode SD2 may be formed with a plurality of layer structures in a manner identical to the first source and drain electrodes E11 and E12.

The light-emitting element OLED may include an anode electrode AND connected to the first drain electrode E12 of the first transistor TFT1, at least one light-emitting stack EL formed on the anode electrode AND, and a cathode electrode CAT formed on the light-emitting stack EL.

The light-emitting stack EL may include a hole injection layer, a hole transport layer, an emission layer, an electron transport layer, and an electron injection layer; in a tandem structure where a plurality of emission layers overlap, a charge generation layer may be additionally disposed between the emission layers. In the case of the emission layer, there may be cases where individual sub-pixels emit different colors.

The anode electrode AND may be connected to the connection electrode SD2 exposed through a contact hole penetrating the second planarization layer PAC2. The anode electrode AND may be formed in a multi-layer structure including a transparent conductive film and an opaque conductive film with high reflection efficiency. The transparent conductive film may be made of a material with a relatively high work function value such as indium-tin-oxide (ITO) or indium-zinc-oxide (IZO), and the opaque conductive film may be formed in a single-layer or multi-layer structure containing Al, Ag, Cu, Pb, Mo, Ti, or an alloy thereof.

For example, the anode electrode AND may be formed in a structure where a transparent conductive film, an opaque conductive film, and a transparent conductive film are stacked in sequence, or may be formed in a three-layer structure like the first source and drain electrodes E11 and E12.

The anode electrode AND may be disposed on the second planarization layer PAC2 so as to overlap not only the emission area provided by the bank BNK but also the pixel circuit area where the first and second transistors TFT1 and TFT2 and the storage capacitor Cst are arranged, increasing the area of emission.

The light-emitting stack EL may be formed by stacking a hole transport layer, an organic emission layer, and an electron transport layer in that order or in the reverse order on the anode electrode AND. In addition, the light-emitting stack EL may further include a charge generation layer, and include first and second light-emitting stacks facing each other with a charge generation layer interposed therebetween.

The bank BNK may be formed to expose the anode electrode AND. This bank BNK may be made of an organic material such as photo acryl, and may be a translucent material, but without being limited thereto. For example, the bank BNK may be made of an opaque material to prevent light interference between sub-pixels. In this case, the bank BNK may include a light shielding material constituted by at least one of a color pigment, organic black, or carbon, without being limited thereto.

For example, the banks BNK may be formed of an organic insulating material. The banks BNK may be composed of a single layer or multiple layers of an organic insulating material. For example, the banks BNK may be composed of a photoresist, a polyimide (PI)-based material, an acryl-based material, or the like, but the exemplary embodiments of the present disclosure are not limited thereto.

Meanwhile, the banks BNK may include an inorganic insulating material, such as silicon nitride (SiNx) or silicon oxide (SiOx), or the bank BNK may be formed of black resin. However, the present disclosure is not limited thereto.

The cathode electrode CAT may be formed on the upper surface of the light-emitting stack EL to face the anode electrode AND with the light-emitting stack EL interposed therebetween. When applied to an organic light-emitting display device of a front-emitting type, the cathode electrode CAT may be provided as a transparent conductive film made of thinned indium-tin-oxide (ITO), indium-zinc-oxide (IZO), or magnesium-silver (Mg—Ag).

An encapsulation layer 300 may be formed on the cathode electrode CAT to protect the light-emitting element OLED. In the light-emitting element OLED, owing to the organic nature of the light-emitting stack EL, a dark spot or pixel shrinkage may occur due to reaction with external moisture or oxygen. To prevent this, the encapsulation layer 300 may be disposed on the cathode electrode CAT.

For example, the encapsulation layer may include a first inorganic encapsulation layer, a first organic encapsulation layer, and a second inorganic encapsulation layer, Alternatively, the encapsulation layer may include a first inorganic encapsulation layer, a first organic encapsulation layer, a second inorganic encapsulation layer, a second organic encapsulation layer, and a third inorganic encapsulation layer stacked sequentially.

The first inorganic encapsulation layer, the second inorganic encapsulation layer, and the third inorganic encapsulation layer may serve to block the penetration of moisture or oxygen. The first inorganic encapsulation layer, the second inorganic encapsulation layer, and the third inorganic encapsulation layer may be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer may each have a larger thickness than each of the first inorganic encapsulation layer, the second inorganic encapsulation layer, and the third inorganic encapsulation layer in order to adsorb or block particles that may be produced during a process of manufacturing the display device. The first organic encapsulation layer and the second organic encapsulation layer may fill cracks that may be formed in the first inorganic encapsulation layer and the second inorganic encapsulation layer. The first organic encapsulation layer and the second organic encapsulation layer may planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer may planarize an upper portion of the first inorganic encapsulation layer by covering particles on the first inorganic encapsulation layer. For example, the second organic encapsulation layer may planarize an upper portion of the second inorganic encapsulation layer by covering particles on the second inorganic encapsulation layer. The first organic encapsulation layer and the second organic encapsulation layer may be made of an organic material, and for example, epoxy polymer, acrylic polymer, or the like may be used. However, the present disclosure is not limited thereto.

Meanwhile, the encapsulation layer is not limited to three or five layers, for example, n layers alternately stacked between inorganic encapsulation layer and organic encapsulation layer (where n is an integer greater than 3) may be included.

The touch sensor layer 18 and the color filter layer 20 may be further disposed on the top of the encapsulation layer 300, but without being limited thereto.

Referring to FIGS. 1 and 3 to 7, the display panel 10 may include the substrate 100 including the first substrate 110 and the second substrate 120 that are arranged adjacent to each other, a pixel array layer 200 arranged on the first substrate 110, the encapsulation layer 300 arranged on the pixel array layer 200, the touch sensor layer 400 arranged on the encapsulation layer 300, the color filter layer 500 arranged on the touch sensor layer 400, a support member 600 arranged between the first substrate 110 and the second substrate 120, and the connection wire 700 arranged on the support member 600. In such a case, since the support member 600 is arranged between the first substrate 110 and the second substrate 120 through a double-sided etching process of the substrate 100, the support member 600 may include a protrusion P that protrudes further than a lower surface of the substrate 100. In addition, edges of the support member 600 may be arranged to overlap the first substrate 110 and the second substrate 120 to protect the connection wire 700. For example, when the back surface (or lower surface) of the substrate 100 is etched while the connection wire 700 is arranged on the substrate 100, fumes may be generated due to a chemical reaction between the substrate 100 and an etching solution and may cause damage to the connection wire 700 through a space between the first substrate 110 and the support member 600 and/or a space between the second substrate 120 and the support member 600. Therefore, the display device according to one exemplary embodiment of the present disclosure may prevent damage to the connection wire 700 due to fumes by using the edges of the support member 600 that overlaps the first substrate 110 and the second substrate 120. Here, the pixel array layer 200 may include a circuit layer 210 arranged on the substrate 100 and a light-emitting element layer 220 arranged on the circuit layer 210, and the circuit layer 210 and the light-emitting element layer 220 may be arranged on the first substrate 110. In addition, phosphoric acid (HNO₃), hydrofluoric acid (HF), etc., may be used as an etching solution.

That is, referring to FIG. 5, one of the edges of the support member 600 may be arranged between the first substrate 110 and the connection wire 700, and the other may be arranged between the second substrate 120 and the connection wire 700.

Referring to FIG. 4, the display panel 10 may further include an insulating layer 130 arranged on the second substrate 120. The insulating layer 130 may be arranged between the second substrate 120 and the connection wire 700.

The insulating layer 130 may be formed as a single layer or a multilayer made of one or an inorganic insulating material and an organic insulating material, or a combination thereof. For example, the insulating layer 130 may be formed as a single layer or a multilayer made of at least one of a multi-buffer layer BUF1, an active buffer layer BUF2, a lower gate insulating layer GI1, an upper gate insulating layer GI2, and an interlayer dielectric layer ILD, or a combination thereof.

The substrate 100 may be made of an insulating material or a material having flexibility. For example, the substrate 100 may be made of glass, metal, plastic, etc., but is not limited thereto. However, the substrate 100 may use a glass substrate having a predetermined strength for an etching process for process simplification. In addition, since the glass substrate is processed through an etching process, a decrease in the rigidity of the glass substrate may be minimized or reduced. Therefore, the rigidity of the glass substrate may be maintained.

A plurality of substrates 100 may be formed through an etching process and a cutting process applied to one mother substrate. Through this, a process of forming the display panel 10 may be simplified, thereby improving the productivity of the display device. In such a case, the substrate 100 may be separated into the first substrate 110 and the second substrate 120 through a double-sided etching process.

The first substrate 110 may include the display area DA and the first non-display area NA1, and may be made of a glass material.

The first substrate 110 may include a first upper surface 111 that contacts the pixel array layer 200, a first lower surface 112 that is an opposite surface of the first upper surface 111, and a first side surface 113 that contacts the support member 600. The first substrate 110 may include a first upper edge UE1 where the first upper surface 111 and the first side surface 113 meet each other, and a first lower edge DE1 where the first lower surface 112 and the first side surface 113 meet each other.

The first upper surface 111 may contact the pixel array layer 200, the encapsulation layer 300, an upper-side edge of the support member 600, and the connection wire 700. In such a case, an organic and/or inorganic insulating layer may be arranged on the first upper surface 111 of the first non-display area NA1, and the connection wire 700 may be arranged on the organic and/or inorganic insulating layer.

The first lower surface 112 may be exposed to the outside, and may form the lower surface of the substrate 100 together with a second lower surface 122 of the second substrate 120. When the display panel 10 is bent, the first lower surface 112 may be arranged to face the second lower surface 122. As the display panel 10 is bent, the protrusion P of the support member 600 may be arranged between the first substrate 110 and the second substrate 120, and may overlap the first substrate 110 and the second substrate 120 in the Z-axis direction.

In order to form the substrate 100 to a predetermined thickness, the entire lower surface of the substrate 100 may be etched. In such a case, the entire lower surface of the substrate 100 may be etched while the support member 600 is arranged between the first substrate 110 and the second substrate 120. Therefore, referring to FIGS. 4 and 5, the first lower edge DE1 may include a rounded curved surface, and a groove H concavely formed may be arranged between the first lower edge DE1 of the first substrate 110 and the support member 600. Accordingly, the first lower surface 112 and the support member 600 may be spaced apart from each other by the groove H.

The first side surface 113 is a surface that connects the first upper surface 111 and the first lower surface 112, and may be a curved surface. For example, the first side surface 113 may include a curved surface because it is formed by partially etching the upper surface of the substrate 100. The first side surface 113 may be referred to as a first etched surface or a first contact surface.

The second substrate 120 may be arranged in the second non-display area NA2 and made of a glass material.

The second substrate 120 may include a second upper surface 121, a second lower surface 122 that is an opposite surface of the second upper surface 121, and a second side surface 123 that contacts the support member 600. In addition, the second substrate 120 may include a second upper edge UE2 where the second upper surface 121 and the second side surface 123 meet each other, and a second lower edge DE2 where the second lower surface 122 and the second side surface 123 meet each other.

The second upper surface 121 may contact the upper-side edge of the support member 600 and the connection wire 700. In addition, the pad portion PAD may be arranged on the second upper surface 121, but is not limited thereto. For example, an organic and/or inorganic insulating layer may be arranged between the second upper surface 121 and the pad portion PAD. Alternatively, the insulating layer 130 may be arranged between the connection wire 700 and the second upper surface 121, but not limited thereto.

The second lower surface 122 may be exposed to the outside, and may form the lower surface of the substrate 100 together with the first lower surface 112 of the first substrate 110. When the display panel 10 is bent, the second lower surface 122 may be arranged to face the first lower surface 112.

In order to form the substrate 100 to a predetermined thickness, the entire lower surface of the substrate 100 may be etched. In such a case, the entire lower surface of the substrate 100 may be etched while the support member 600 is arranged between the first substrate 110 and the second substrate 120. Therefore, the second lower edge DE2 may include a rounded curved surface, and a groove H concavely formed may be arranged between the second lower edge DE2 of the second substrate 120 and the support member 600. Accordingly, referring to FIGS. 4 and 5, the second lower surface 122 and the support member 600 may be spaced apart from each other by the groove H. The groove H between the first substrate 110 and the support member 600 and the groove H between the second substrate 120 and the support member 600 facilitate the bending of the display panel 10. For example, in a case where a plate-shaped member is bent, when there is a notch in the plate-shaped member, the plate-shaped member is easily bent. In this way, since the groove H of the display panel 10 may perform the same role as the notch of the plate-shaped member, the groove H of the display panel 10 facilitates the bending of the display panel 10. Referring to FIG. 5, at two sides of the support member 600, the grooves H are formed between the first lower edge DE1 of the first substrate 110 and the support member 600, and between the second lower edge DE2 of the second substrate 120 and the support member 600, respectively, but the present disclosure is not limited thereto. Meanwhile, a number of the grooves H at two sides of the support member 600 each may be one or more, but not limited thereto.

The second side surface 123 is a surface that connects the second upper surface 121 and the second lower surface 122, and may be a curved surface. For example, the second side surface 123 may include a curved surface because it is formed by partially etching the upper surface of the substrate 100. The second side surface 123 may be referred to as a second etched surface or a second contact surface.

The circuit layer 210 may include pixel circuits connected to wires such as data lines, gate lines, and power lines, gate drivers GIPs connected to the gate lines, etc. The wires and circuit elements of the circuit layer 210 may include a plurality of insulating layers, two or more metal layers separated by the insulating layers, and an active layer including a semiconductor material.

The light-emitting element layer 220 may include a light-emitting element OLED driven by the pixel circuit. The light-emitting element OLED may include a red light-emitting element, a green light-emitting element, and a blue light-emitting element. In another exemplary embodiment, the light-emitting element layer 220 may include a white light-emitting element and a color filter. The light-emitting elements of the light-emitting element layer 220 may be covered by a protective layer including an organic film and a protective film.

The encapsulation layer 300 covers the light-emitting element layer 220 to seal the circuit layer 210 and the light-emitting element layer 220. The encapsulation layer 300 may be a multi-insulating film structure in which organic films and inorganic films are alternately stacked. In such a case, the inorganic film blocks the penetration of moisture or oxygen. The organic film planarizes the surface of the inorganic film. When the organic film and the inorganic film are stacked in multiple layers, the migration path of moisture or oxygen becomes longer compared to a single layer, so that the penetration of moisture/oxygen that affects the light-emitting element layer 220 may be effectively blocked.

The touch sensor layer 400 may include capacitive touch sensors that sense touch input based on a change in capacitance before and after the touch input. The touch sensor layer 400 may include metal wire patterns and insulating films that form the capacitance of the touch sensors. The insulating films may insulate intersection portions of the metal wire patterns and planarize the surface of the touch sensor layer.

A polarizing plate (not shown in the drawing) may be adhered onto the touch sensor layer 400. The polarizing plate may improve the visibility and contrast ratio by converting polarization of external light reflected by the metal patterns of the circuit layer 210. The polarizing plate may be implemented as a polarizing plate in which a linear polarizing plate and a phase delay film are bonded, or a circular polarizing plate.

The color filter layer 500 may be formed on the touch sensor layer 400.

The color filter layer 500 may include red, green, and blue color filters CF. The color filter layer 500 may further include a black matrix pattern BM. The color filter layer 500 may absorb a part of the wavelength of light reflected from the circuit layer 210 to replace the role of the polarizing plate and increase color purity. The display panel 10 arranged with the color filter layer 500 may improve the light transmittance of the display panel 10 and improve the thickness and flexibility of the display panel 10 by applying the color filter layer 500 having a higher light transmittance than the polarizing plate to the display panel 10. A cover glass 900 may be adhered onto the color filter layer 500 by using an adhesive member 510.

The color filter layer 500 may include an organic film that covers the color filter and the black matrix pattern. An extended portion of the organic film may cover an inorganic film residue or the substrate 100 in a bezel area of the display panel 10, i.e., an edge area.

The support member 600 may be arranged between the first substrate 110 and the second substrate 120 based on the Y-axis direction. For example, a partial etching process may be used to etch a part of the upper surface of the substrate 100, the support member 600 may be arranged in the etched area, and then the entire lower surface of the substrate 100 may be etched. Therefore, the substrate 100 may be separated into the first substrate 110 and the second substrate 120, and the support member 600 may be arranged between the first substrate 110 and the second substrate 120. In such a case, the protrusion P of the support member 600 may be arranged to protrude further than the lower surface of the substrate 100. Therefore, the thickness of a partial area of the support member 600 is thicker than the thickness of the substrate 100.

Referring to FIGS. 4 and 5, the support member 600 may be formed so that an upper-side width of the support member 600 is greater than a lower-side width of the support member 600. The upper-side edge of the support member 600 may contact the first upper surface 111 of the first substrate 110 and the second upper surface 121 of the second substrate 120. Therefore, the upper-side edge of the support member 600 may overlap the first upper surface 111 of the first substrate 110 and the second upper surface 121 of the second substrate 120, so that the connection wire 700 may be protected from fumes.

The support member 600 may be arranged in the bending area BA, and may be bent by the bending of the display panel 10. For the bending of the display panel 10, the support member 600 may include a flexible material, and may include an acrylic-based organic material, a silicon-based organic material, etc.

The support member 600 may be made of one material, but is not necessarily limited thereto. As shown in FIG. 5, the support member 600 may also be formed using two or more materials. For example, the support member 600 may include a lower coating layer 610 and a wire protective layer 620 made of different materials.

Referring to FIG. 5, the support member 600 may include a lower coating layer 610 and a wire protective layer 620. The lower coating layer 610 may be referred to as a lower support portion.

The lower coating layer 610 may contact the first side surface 113 of the first substrate 110 and the second side surface 123 of the second substrate 120.

The lower coating layer 610 may be arranged between the first side surface 113 of the first substrate 110 and the second side surface 123 of the second substrate 120, and may overlap the first substrate 110 and the second substrate 120 in the Y-axis direction. Therefore, an upper surface of the lower coating layer 610 may be arranged on the same plane as the first upper surface 111 of the first substrate 110 and the second upper surface 121 of the second substrate 120.

The lower coating layer 610 may be formed in a taper shape in which an upper-side width of the lower coating layer 610 is greater than a lower-side width of the lower coating layer 610. For example, a first width W1 of the lower coating layer 610 may decrease downward. For example, the lower coating layer 610 may be formed in a reverse taper shape in which an upper-side width of the lower coating layer 610 is greater than a lower-side width of the lower coating layer 610, but not limited thereto. The side surface of the lower coating layer 610 may be formed in a shape corresponding to the first side surface 113 of the first substrate 110 and the second side surface 123 of the second substrate 120, and may include a curved surface.

A lower part of the lower coating layer 610 may be arranged to protrude further than the lower surface of the substrate 100, and the lower part of the lower coating layer 610 that protrudes further than the lower surface of the substrate 100 may be referred to as a protrusion. For example, the protrusion P of the support member 600 may be a protrusion of the lower coating layer 610.

The lower coating layer 610 may be made of an organic material including a polyester-based polymer, an acrylic-based polymer, etc.

The wire protective layer 620 may be arranged on the lower coating layer 610, and may be formed in a plate shape having a flat surface.

Alternatively, the wire protective layer 620 may be formed to correspond to a part of the connection wire 700. For example, since the connection wire 700 is arranged on the first substrate 110, the second substrate 120, and the wire protective layer 620, the wire protective layer 620 may be formed in the same shape as a part of the connection wire 700.

A second width W2 of the wire protective layer 620 may be formed to be greater than the first width W1 of the lower coating layer 610, and the wire protective layer 620 may cover an upper part of the lower coating layer 610. Therefore, an edge of the wire protective layer 620 may contact the first upper surface 111 of the first substrate 110 and the second upper surface 121 of the second substrate 120. The edge of the wire protective layer 620 may be arranged to overlap the first upper surface 111 of the first substrate 110 and the second upper surface 121 of the second substrate 120, thereby covering the upper part of the first side surface 113 of the first substrate 110 and the upper part of the second side surface 123 of the second substrate 120.

A material of the wire protective layer 620 may be different from a material of the lower coating layer 610. For example, the wire protective layer 620 may include one selected from the group consisting of a polyester-based polymer, a silicone-based polymer, an acrylic-based polymer, a polyolefin-based polymer, and a copolymer thereof. For example, the wire protective layer 620 may be made of polyimide.

The connection wire 700 may be arranged on the wire protective layer 620.

Therefore, damage to the connection wire 700 due to fumes, etc., may be prevented due to the arrangement position, structure, material, etc., of the wire protective layer 620 on the display panel 10.

The connection wire 700 may include various conductive materials.

The connection wire 700 may be formed as a multilayer stacked structure. Referring to FIG. 5, the connection wire 700 may be formed as a triple layer structure including a first layer 710 arranged on the wire protective layer 620, a second layer 720 arranged on the first layer 710, and a third layer 730 arranged on the second layer 720.

In such a case, at least one layer implementing the connection wire 700 may include a metal having relatively low reactivity with fumes so that the connection wire 700 may be prevented from being damaged by fumes, etc., that may occur during the manufacturing process as described above.

That is, the first layer 710, the second layer 720, and the third layer 730 of the connection wire 700 may be made of the same material, but are not necessarily limited thereto. At least one of the first layer 710, the second layer 720, and the third layer 730 of the connection wire 700 may be made of a different material. For example, the connection wire 700 may be formed of the first layer 710 made of titanium (Ti), the second layer 720 made of aluminum (Al), the third layer 730 made of titanium (Ti), or may be formed of the first layer 710 made of molybdenum (Mo), the second layer 720 made of aluminum (Al), and the third layer 730 made of titanium (Ti). In such a case, in consideration of the conductivity of the connection wire 700, the thickness of the second layer 720 may be greater than thicknesses of the first layer 710 and the third layer 730. For example, since aluminum (Al) has good conductivity and ductility, the thickness of the second layer 720 made of aluminum (Al) may be made greater than the thicknesses of the first layer 710 and the third layer 730. Therefore, the connection wire 700 may easily cope with the bending of the display panel 10 while lowering the resistivity of the connection wire 700.

Accordingly, the display device according to one exemplary embodiment of the present disclosure may prevent damage to the connection wire 700 by blocking fumes by using the support member 600 having a wide upper-side width as shown in FIG. 4 or the wire protective layer 620 constituting the support member 600 as shown in FIG. 5. In addition, the display device according to one exemplary embodiment of the present disclosure may prevent damage to the connection wire 700 due to fumes by putting a material having low reactivity with fumes, such as titanium (Ti) or molybdenum (Mo), into the first layer 710. In such a case, molybdenum (Mo) has lower reactivity with fumes than titanium (Ti). For example, the connection wire 700 may be formed of a first layer 710 made of molybdenum (Mo), a second layer 720 made of aluminum (Al), and a third layer 730 made of titanium (Ti). Therefore, the materials of the first layer 710, the second layer 720, and the third layer 730 may be different from one another.

The thickness of the first layer 710 made of molybdenum (Mo) may be greater than the thickness of the third layer 730 made of titanium (Ti). For example, since molybdenum (Mo) has better tensile properties than titanium (Ti), the thickness of the first layer 710 made of molybdenum (Mo) may be made greater than the thickness of the third layer 730 made of titanium (Ti), thereby easily coping with the bending of the display panel 10.

The connection wire 700 may be made of one of various conductive materials used in the display area DA. For example, the plurality of connection wires 700 may be formed in a triple layer structure like the first source and drain electrodes E11 and E12 and the second source and drain electrodes E21 and E22 arranged in the display area DA. Therefore, the plurality of connection wires 700 may be simultaneously formed with the first source and drain electrodes E11 and E12 and the second source and drain electrodes E21 and E22 in a single mask process. Accordingly, the display device according to one exemplary embodiment of the present disclosure may improve the productivity of the display panel 10 by configuring the first source and drain electrodes E11 and E12, the second source and drain electrodes E21 and E22, and the connection wire 700 together without a separate process of configuring the connection wire 700. The connection wire 700 is formed together with the first source and drain electrodes E11 and E12 and the second source and drain electrodes E21 and E22 as an example, but is not necessarily limited thereto. For example, the connection wire 700 may also be formed with the connection electrode SD2 of the display area DA, and the connection electrode SD2 may be formed in a multilayer structure like the connection wire 700. The display panel 10 may further include at least one of an upper coating layer 800 and a planarization layer 810 arranged on the connection wire 700. For example, the upper coating layer 800 may be arranged on the connection wire 700, or the planarization layer 810 may be arranged on the connection wire 700, or the planarization layer 810 may be arranged on the connection wire 700 and the upper coating layer 800 may be arranged on the planarization layer 810.

The planarization layer 810 may be arranged on the connection wire 700 to protect the connection wires 700 from physical and/or chemical impacts. For example, the planarization layer 810 may prevent moisture, impurities, etc., from penetrating into the connection wires 700.

The planarization layer 810 may be made of one or more of acrylic resin, epoxy resin, phenol resin, polyamide resin, polyimide resin, unsaturated polyester resin, polyphenylene resin, polyphenylene sulfide resin, and benzocyclobutene, but is not limited thereto.

The planarization layer 810 may be made of one of the materials used in the display area DA. For example, the planarization layer 810 may be formed in the same process together with the first planarization layer PAC1 and/or the second planarization layer PAC2. Therefore, the planarization layer 810 may be configured together with the first planarization layer PAC1 and/or the second planarization layer PAC2 to improve the productivity of the display panel 10.

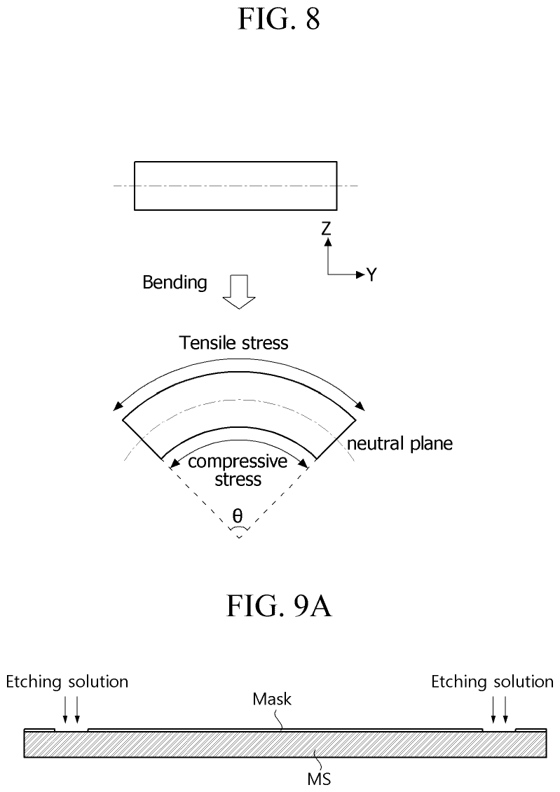

The planarization layer 810 may be formed to have a predetermined first thickness T1. By adjusting the first thickness T1, stress applied to the connection wire 700 may be minimized. FIG. 8 is a view showing a neutral plane according to bending.

Referring to FIG. 8, the neutral plane may be defined as a plane where a stress state is 0 during bending, and the size of tensile stress or compressive stress is determined in proportion to a distance from the neutral plane. The neutral plane may be positioned in the center between a plane where the tensile stress is applied and a plane where the compressive stress is applied, based on the Z direction. The plane where the compressive stress is applied may be defined as a plane arranged close to the center of curvature, and the plane where the tensile stress is applied may be defined as an opposite plane of the plane where the compressive stress is applied.

In addition, cracks are more likely to occur in a configuration arranged in an area where the tensile stress is applied than in a configuration arranged in an area where the compressive stress is applied. For example, since the connection wire 700 arranged in the bending area BA of the display panel 10 may be arranged in an area where the tensile stress is applied, there is a relatively high probability that cracks will occur in the connection wire 700 due to bending of the bending area BA, compared to the lower coating layer 610. Therefore, since cracks are more likely to occur in an area subject to the tensile stress than in an area subject to the compressive stress during bending, the stress applied to the connection wire 700 may be minimized by moving the neutral plane to be closer to the connection wire 700.

Therefore, referring to FIG. 5, when the planarization layer 810 is arranged on the connection wire 700, the display device according to one exemplary embodiment of the present disclosure may position the neutral plane on or closer to the connection wire 700 by adjusting the first thickness T1 of the planarization layer 810 while the thickness from the substrate 100 to the connection wire 700 is determined. Therefore, the display panel 10 may reduce stress applied to the connection wire 700 during the bending of the display panel 10 by using the planarization layer 810.

The upper coating layer 800 may be arranged on the connection wire 700 or on the planarization layer 810. Therefore, the upper coating layer 800 may be arranged on the connection wire 700 to protect the connection wires 700 from physical and/or chemical impacts. For example, the upper coating layer 800 may prevent moisture, impurities, etc., from penetrating into the connection wires 700.

The upper coating layer 800 may be made of the same material as the lower coating layer 610, but is not necessarily limited thereto. For example, in consideration of the position of the neutral plane, the upper coating layer 800 may be made of an organic insulating material different from the lower coating layer 610.

Referring to FIG. 5, the upper coating layer 800 may be formed to have a predetermined second thickness T2. Therefore, when the upper coating layer 800 is arranged on the connection wire 700, the display device according to one exemplary embodiment of the present disclosure may position the neutral plane on or closer to the connection wire 700 by adjusting the second thickness T2 of the upper coating layer 800 while the thickness from the substrate 100 to the connection wire 700 or from the substrate 100 to the planarization layer 810 is determined. Therefore, the display panel 10 may reduce stress applied to the connection wire 700 during the bending of the display panel 10 by using the upper coating layer 800.

In addition, while the first thickness T1 of the planarization layer 810 and the thickness T2 of the upper coating layer 800 are determined, the neutral plane may be positioned on or closer to the connection wire 700 by adjusting the thickness of the connection wire 700.

In order to position the neutral surface on or close to the connection wire 700, the thicknesses of the substrate 100 and the support member 600 also need to be considered.

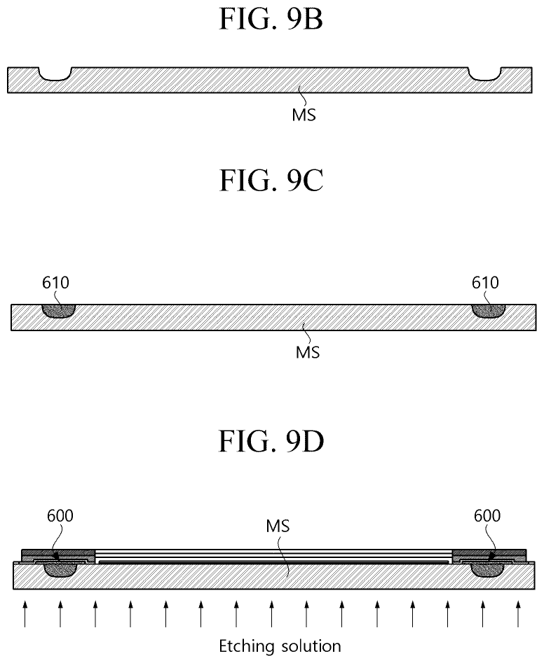

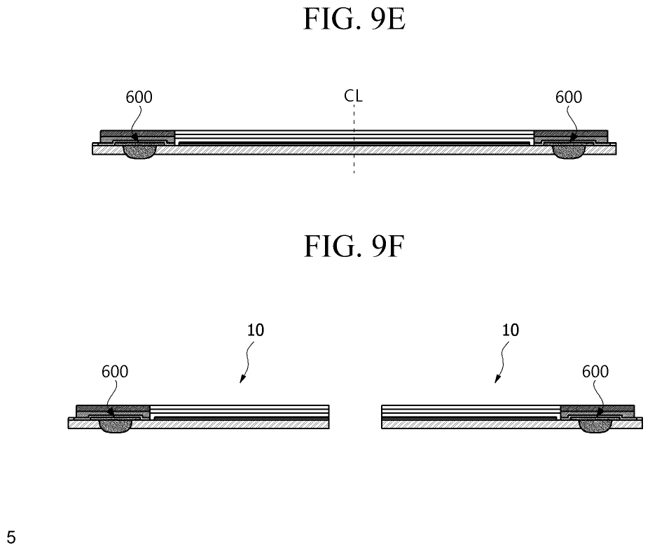

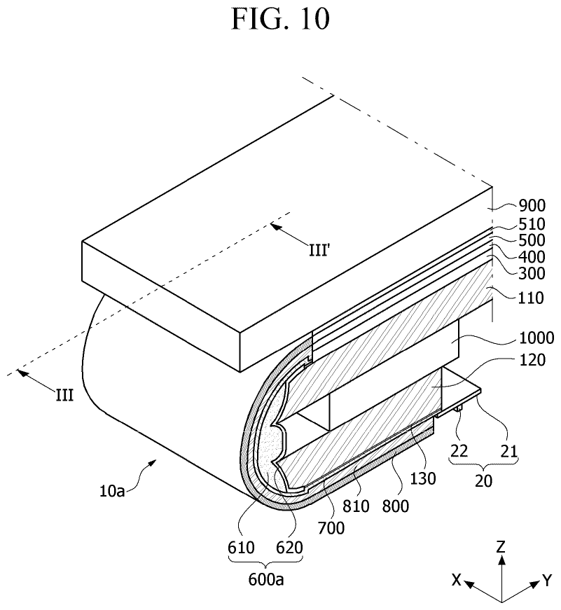

FIG. 9A, FIG. 9B, FIG. 9C, FIG. 9D, FIG. 9E and FIG. 9F are views showing a manufacturing process of the display panel according to one exemplary embodiment of the present disclosure. For example, FIG. 9A is a view showing a mask arranged in order to partially etch the upper surface of the mother substrate. FIG. 9B is a view showing a groove formed on the upper surface of the mother substrate by partial etching. FIG. 9C is a view showing the lower coating layer 610 arranged in the groove of the mother substrate. FIG. 9D is a view showing the lower etching of the mother substrate on which the pixel array layer 200, the encapsulation layer 300, the touch sensor layer 400, the color filter layer 500, the wire protective layer 620, the connection wire 700, etc., are arranged. FIG. 9E is a view showing the mother substrate subject to the lower etching. FIG. 9F is a view showing a plurality of display panels 10 separated by a cutting process.

Referring to FIGS. 9A and 9B, a plurality of grooves may be formed in the upper surface of the mother substrate MS by etching a part of the upper surface of the mother substrate MS by using a patterned mask and an etching solution. Since the plurality of grooves are formed in the upper surface of the mother substrate MS through a single etching process, the manufacturing process of the display panel 10 may be simplified.

Referring to FIG. 9C, the lower coating layer 610 may be arranged in each of the plurality of grooves formed in the upper surface of the mother substrate MS.

Referring to FIGS. 9D and 9E, the pixel array layer 200, the encapsulation layer 300, the touch sensor layer 400, the color filter layer 500, the wire protective layer 620, the connection wire 700, etc., may be arranged on the upper surface of the mother substrate MS on which the lower coating layer 610 is arranged. Subsequently, by etching the lower surface of the mother substrate MS by using an etching solution, the thickness of the mother substrate MS may be adjusted. As the lower part of the mother substrate MS is etched, the mother substrate MS may be distinguished to correspond to the first substrate 110 and the second substrate 120 of the substrate 100 based on the lower coating layer 610. Since the lower etching process is performed on the mother substrate MS through a single etching process, the manufacturing process of the display panel 10 may be simplified.

Referring to FIG. 9F, by performing a cutting process along a cutting line CL, the plurality of display panels 10 may be separated, respectively.

The display panel 10 according to one exemplary embodiment of the present disclosure may further include a cover layer for example, a cover glass 900 that may be adhered to the color filter layer 500 through an adhesive member.

The cover layer/cover glass 900 may be arranged to cover the display area DA and the bending area BA of the display panel 10. Therefore, the cover glass 900 may protect other components of the display panel 10 from physical and/or chemical impacts.

The cover layer may be made of a transparent plastic material, a normal glass material, or a reinforced glass material.

The display panel 10 according to one exemplary embodiment of the present disclosure may further include a functional member 1000 arranged between the lower surface 112 of the first substrate 110 and the lower surface 122 of the second substrate 120.

The functional member 1000 may be arranged to be in contact between the first substrate 110 and the second substrate 120 and may support the first substrate 110 and the second substrate 120. Therefore, the functional member 1000 may serve as a support member so that the first substrate 110 and the second substrate 120 maintain a preset gap.

The functional member 1000 may also serve as a heat sink. For example, the functional member 1000 may be made of a metal material such as aluminum having high thermal conductivity, but not limited thereto. Therefore, heat generated from the display panel 10 may be dissipated through the functional member 1000.

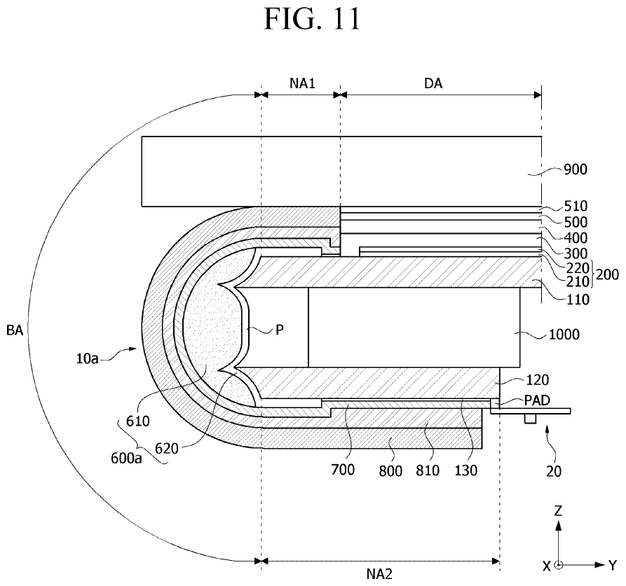

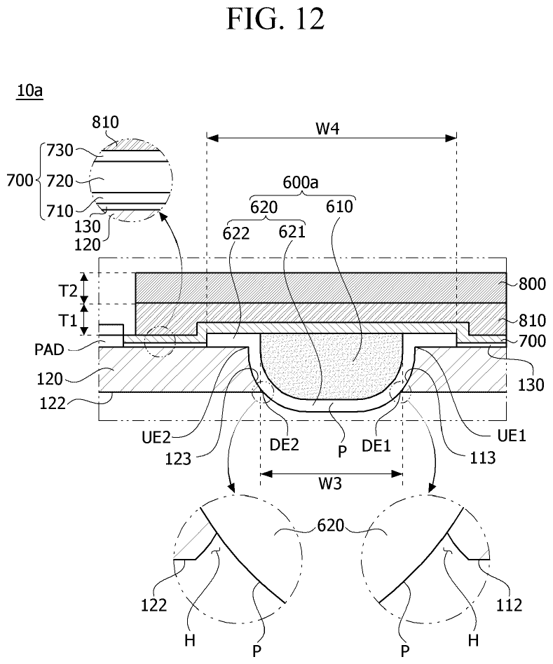

FIG. 10 is a perspective view showing a bent appearance of a display device according to another exemplary embodiment of the present disclosure. FIG. 11 is a cross-sectional view taken along line III-III′ in FIG. 10. FIG. 12 is a view showing the display device according to another exemplary embodiment of the present disclosure based on the area B in FIG. 4. A display panel 10a shown in FIGS. 10 to 12 may be a display panel according to a second exemplary embodiment. In addition, a support member 600a shown in FIGS. 10 to 12 may be a support member according to the second exemplary embodiment.

When the display panel 10 according to the first exemplary embodiment and the display panel 10a according to the second exemplary embodiment are compared with each other with reference to FIGS. 5 and 12, the display panel 10a according to the second exemplary embodiment is different from the display panel 10 according to the first exemplary embodiment in the arrangement positions of the lower coating layer 610 and the wire protective layer 620. Therefore, the connection wire 700 may contact both the lower coating layer 610 and the wire protective layer 620, and the wire protective layer 620 may be exposed.

In describing the display panel 10a according to the second exemplary embodiment with reference to FIGS. 10 to 12, since identical or substantially identical components between the display panel 10 according to the first exemplary embodiment and the display panel 10a according to the second exemplary embodiment may be denoted by the same reference numerals, detailed description thereof is omitted.

However, the arrangement positions of the lower coating layer 610 and the wire protective layer 620 constituting the support member 600a of the display panel 10a may be different from those of the first exemplary embodiment, and the materials of the lower coating layer 610 and the wire protective layer 620 may be different from those of the first exemplary embodiment. Therefore, even if the lower etching process of the substrate 100 is performed while the materials of the lower coating layer 610 and the wire protective layer 620 are different from those of the first exemplary embodiment, the shape of the support member 600a may be maintained, and thus damage to the connection wire 700 may be more effectively prevented in response to stress caused by the bending of the bending area BA.

Referring to FIGS. 11 and 12, the insulating layer 130 may be arranged on the first substrate 110 and the second substrate 120 of the display panel 10a, and may overlap the wire protective layer 620 and the connection wire 700 (see FIG. 4).

Referring to FIG. 12, the support member 600a of the display panel 10a according to the second exemplary embodiment may include the lower coating layer 610, and the wire protective layer 620 surrounding the lower coating layer 610. Therefore, the connection wire 700 may be arranged on the lower coating layer 610 and the wire protective layer 620.

The wire protective layer 620 may include a body part 621 surrounding the lower coating layer 610 and a flange part 622 extending horizontally from an upper end of the body part 621.

The body part 621 may be formed in a tubular shape with an accommodation space formed therein. For example, a groove may be formed to accommodate the lower coating layer 610, and since the lower coating layer 610 is arranged in the groove, the body part 621 may contact the first side surface 113 of the first substrate 110 and the second side surface 123 of the second substrate 120.

The flange part 622 may contact a part of the upper surface 111 of the first substrate 110 and a part of the upper surface 121 of the second substrate 120, and overlap the first substrate 110 and the second substrate 120. Therefore, the wire protective layer 620 may contact a part of the upper surface 111 of the first substrate 110 and a part of the upper surface 121 of the second substrate 120.

The lower part of the wire protective layer 620 may be arranged to protrude further than the lower surface of the substrate 100, and the lower part of the wire protective layer 620 that protrudes further than the lower surface of the substrate 100 may be referred to as a protrusion. For example, the protrusion P of the support member 600a may be a protrusion of the wire protective layer 620.

The lower coating layer 610 may be arranged in the inner part (or inside) of the body part 621, and may form the support member 600a together with the wire protective layer 620. Therefore, an upper surface of the lower coating layer 610 may contact the connection wire 700. In such a case, a third width W3 of the lower coating layer 610 in contact with the connection wire 700 may be smaller than a fourth width W4 of the wire protective layer 620 in contact with the connection wire 700. An area of the wire protective layer 620 in contact with the connection wire 700 may be the flange part 622, and the fourth width W4 may be a width of the flange part 622.

Accordingly, a contact area between the lower coating layer 610 and the connection wire 700 may be greater than a contact area between the wire protective layer 620 and the connection wire 700.

The lower coating layer 610 may overlap the first substrate 110 and the second substrate 120 in the Y-axis direction.

The lower coating layer 610 may be formed in a shape in which an upper-side width of the lower coating layer 610 is greater than a lower-side width of the lower coating layer 610. For example, the width of the lower coating layer 610 may decrease downward. The lower coating layer 610 may be formed in a reverse taper shape in which an upper-side width of the lower coating layer 610 is greater than a lower-side width of the lower coating layer 610. However, the present disclosure is not limited thereto.

A material of the lower coating layer 610 may be different from a material of the wire protective layer 620, and the lower coating layer 610 may contact the connection wire 700 in a wider area than the wire protective layer 620.

In addition, the material of the lower coating layer 610 may use a material having better ductility than the material of the wire protective layer 620. Therefore, since the material of the lower coating layer 610 has greater ductility than the material of the wire protective layer 620, the phenomenon of the lower coating layer 610 being split or cracked due to stress occurring during the bending of the bending area BA may be prevented.

Accordingly, the support member 600a supports the connection wire 700 by using the lower coating layer 610 having good ductility, thereby implementing a robust structure that copes with stress caused by bending.

The chemical resistance of the wire protective layer 620 may be higher than the chemical resistance of the lower coating layer 610. The chemical resistance may mean the degree of non-reaction to an etching solution, and a layer with high chemical resistance may be relatively less etched. For example, the support member 600a according to the second exemplary embodiment may be less etched than a case where the lower coating layer 610 of the support member 600 according to the first exemplary embodiment is exposed.

Accordingly, even though the support member 600a is exposed to an etching solution by a lower etching process, the wire protective layer 620 with high chemical resistance may be used to cope with the lower etching process. Since the lower coating layer 610 is also a material with higher chemical resistance than the substrate 100, the lower coating layer 610 may also cope with the lower etching process even in the case of the support member 600 according to the first exemplary embodiment.

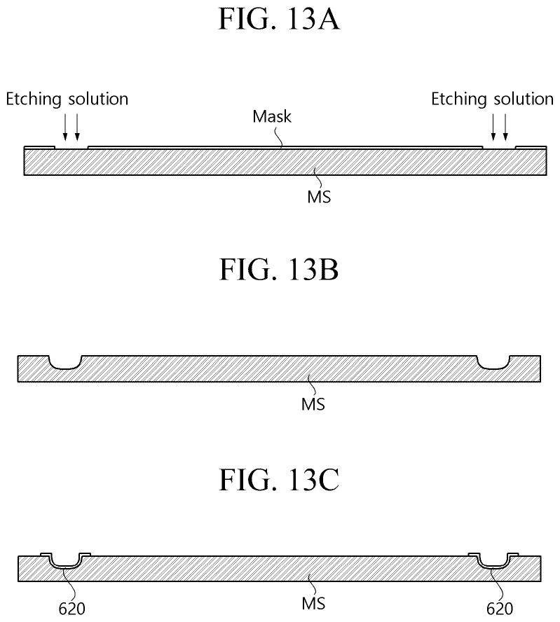

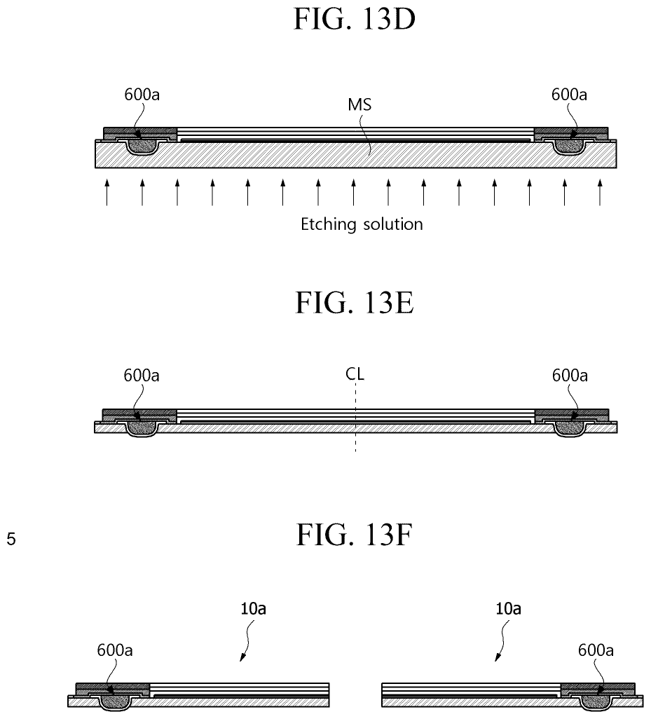

FIG. 13A, FIG. 13B, FIG. 13C, FIG. 13D, FIG. 13E and FIG. 13F are views showing a manufacturing process of the display panel according to another exemplary embodiment of the present disclosure.

FIGS. 13A to 13F are views showing the manufacturing process of the display panel according to another exemplary embodiment of the present disclosure. For example, FIG. 13A is a view showing a mask arranged in order to partially etch the upper surface of a mother substrate. FIG. 13B is a view showing a groove formed in the upper surface of the mother substrate by partial etching. FIG. 13C is a view showing the wire protective layer 620 arranged in the groove of the mother substrate. FIG. 13D is a view showing the lower etching of the mother substrate on which the pixel array layer 200, the encapsulation layer 300, the touch sensor layer 400, the color filter layer 500, the wire protective layer 620, and the connection wire 700 are arranged. FIG. 13E is a view showing the mother substrate subject to the lower etching. FIG. 13F is a view showing a plurality of display panels 10 separated by a cutting process.

Referring to FIGS. 13A and 13B, a plurality of grooves may be formed in the upper surface of the mother substrate MS by etching a part of the upper surface of the mother substrate MS by using a patterned mask and an etching solution. Since the plurality of grooves are formed in the upper surface of the mother substrate MS through a single etching process, the manufacturing process of the display panel 10a may be simplified.

Referring to FIG. 13C, the wire protective layer 620 may be arranged in each of the plurality of grooves formed in the upper surface of the mother substrate MS.

Referring to FIGS. 13D and 13E, the pixel array layer 200, the encapsulation layer 300, the touch sensor layer 400, the color filter layer 500, the connection wire 700, etc., may be arranged on the upper surface of the mother substrate MS on which the lower coating layer 610 is arranged. In such a case, the connection wire 700 may be arranged on the lower coating layer 610 and the wire protective layer 620, and a contact area between the lower coating layer 610 and the connection wire 700 may be greater than a contact area between the wire protective layer 620 and the connection wire 700. Subsequently, by etching the lower surface of the mother substrate MS by using an etching solution, the thickness of the mother substrate MS may be adjusted. As the lower part of the mother substrate MS is etched, the mother substrate MS may be distinguished to correspond to the first substrate 110 and the second substrate 120 of the substrate 100 based on the lower coating layer 610. In such a case, the wire protective layer 620 may be arranged to protrude further than the lower surface of the substrate 100 by the lower etching process. Since the lower etching process is performed on the mother substrate MS through a single etching process, the manufacturing process of the display panel 10a may be simplified.

Referring to FIG. 13F, by performing a cutting process along a cutting line CL, the plurality of display panels 10a may be separated, respectively.

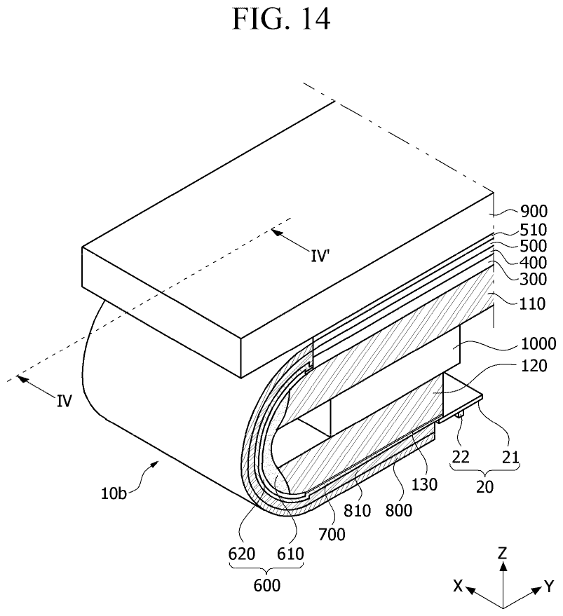

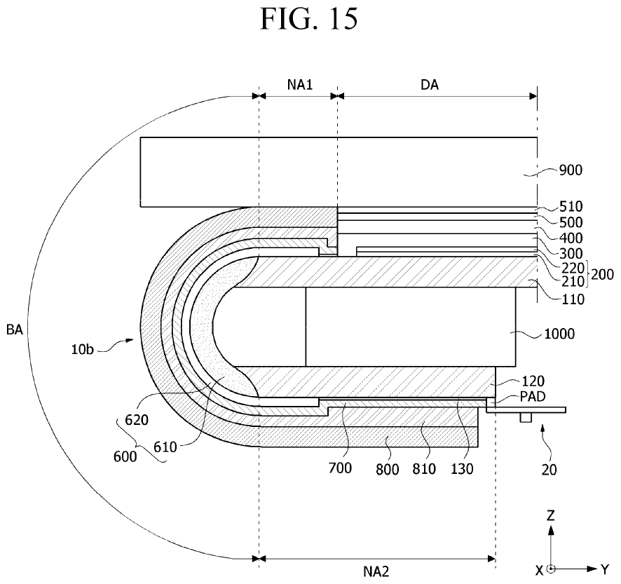

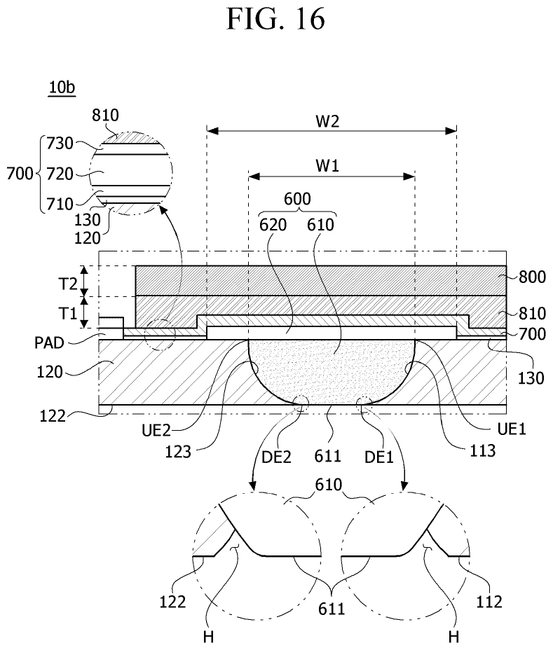

FIG. 14 is a perspective view showing a bent appearance of a display device according to another exemplary embodiment of the present disclosure. FIG. 15 is a cross-sectional view taken along line IV-IV′ in FIG. 14. FIG. 16 is a view showing the display device according to another exemplary embodiment of the present disclosure based on the area B in FIG. 4. A display panel 10b shown in FIGS. 14 to 16 may be a display panel according to a third exemplary embodiment.

When the display panel 10 according to the first exemplary embodiment and the display panel 10b according to the third exemplary embodiment are compared with each other with reference to FIGS. 5 and 16, the display panel 10b according to the third exemplary embodiment has a difference in the arrangement relationship between the substrate 100 and the support member 600.

In describing the display panel 10b according to the third exemplary embodiment with reference to FIGS. 14 to 16, since identical or substantially identical components between the display panel 10 according to the first exemplary embodiment and the display panel 10b according to the third exemplary embodiment may be denoted by the same reference numerals, detailed description thereof is omitted.

However, the position of the lower surface of the support member 600 of the display panel 10b according to the third exemplary embodiment may be different from the position of the lower surface of the support member 600 of the display panel 10 according to the first exemplary embodiment. Therefore, when the display panel 10b is bent, the lower coating layer 610 may be concavely formed toward the connection wire 700 to have a predetermined radius of curvature (see FIGS. 14 and 15).

Referring to FIG. 16, the entire substrate 100 may be etched while the support member 600 is arranged between the first substrate 110 and the second substrate 120. Therefore, the first lower edge DE1 of the first substrate 110 may include a rounded curved surface, and a groove H concavely formed may be arranged between the first lower surface 112 of the first substrate 110 and the lower surface 611 of the support member 600. Accordingly, the first lower surface 112 of the first substrate 110 and the lower surface 611 of the support member 600 may be spaced apart from each other by the groove H. In addition, the second lower edge DE2 may include a rounded curved surface, and a groove H concavely formed may be arranged between the second lower surface 122 of the second substrate 120 and the lower surface 611 of the support member 600. Accordingly, the second lower surface 122 of the second substrate 120 and the lower surface 611 of the support member 600 may be spaced apart from each other by the groove H. Referring to FIG. 16, at two sides of the support member 600, the grooves H are formed between the first lower surface 112 of the first substrate 110 and the lower surface 611 of the support member 600, and between the second lower surface 122 of the second substrate 120 and the lower surface 611 of the support member 600, respectively, but the present disclosure is not limited thereto. Meanwhile, a number of the grooves H at two sides of the support member 600 each may be one or more, but not limited thereto.

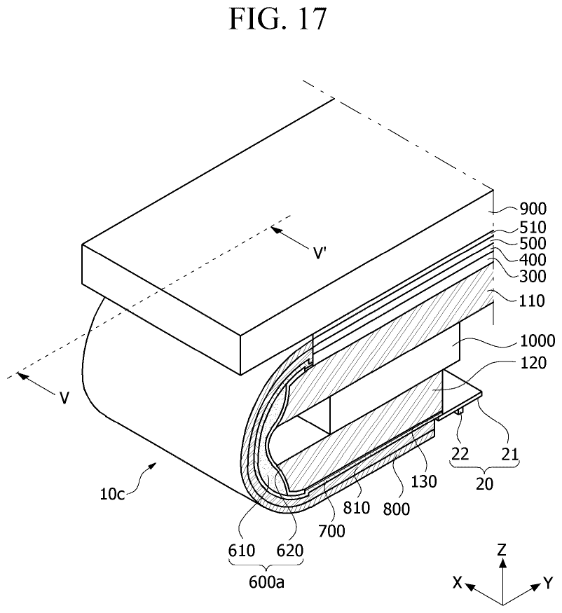

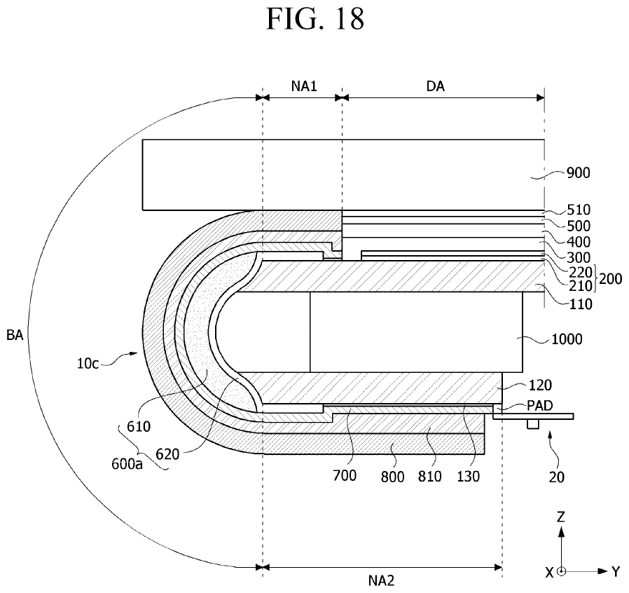

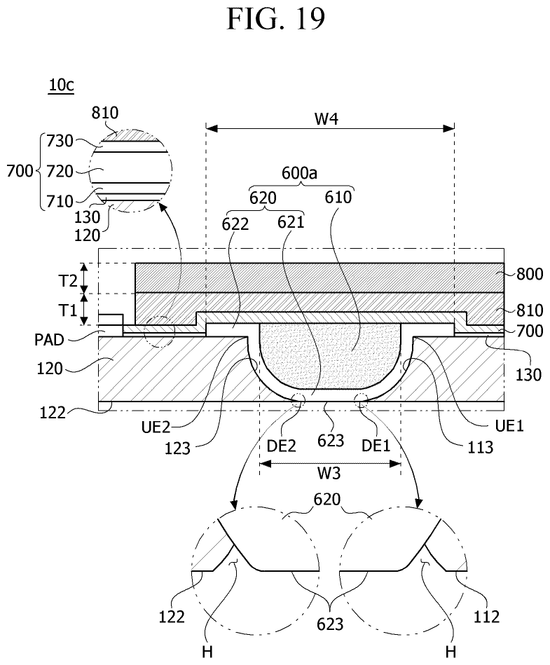

FIG. 17 is a perspective view showing a bent appearance of a display device according to another exemplary embodiment of the present disclosure. FIG. 18 is a cross-sectional view taken along line V-V′ in FIG. 17. FIG. 19 is a view showing the display device according to another exemplary embodiment of the present disclosure based on the area B in FIG. 4. A display panel 10c shown in FIGS. 17 to 19 may be a display panel according to a fourth exemplary embodiment.

When the display panel 10a according to the second exemplary embodiment and the display panel 10c according to the fourth exemplary embodiment are compared with each other with reference to FIGS. 12 and 19, the display panel 10c according to the fourth exemplary embodiment has a difference in the arrangement relationship between the substrate 100 and the support member 600a.

In describing the display panel 10c according to the fourth exemplary embodiment with reference to FIGS. 17 to 19, since identical or substantially identical components between the display panel 10a according to the second exemplary embodiment and the display panel 10c according to the fourth exemplary embodiment may be denoted by the same reference numerals, detailed description thereof is omitted.

The support member 600a may include the lower coating layer 610, and the wire protective layer 620 surrounding the lower coating layer 610. In addition, the wire protective layer 620 may include the body part 621 surrounding the lower coating layer 610 and the flange part 622 extending horizontally from the upper end of the body part 621.

In addition, the display panel 10c according to the fourth exemplary embodiment may further include the insulating layer 130 arranged on the second substrate 120 (see FIG. 4).

The support member 600a may be arranged between the first substrate 110 and the second substrate 120 through a double-sided etching process of the substrate 100, and the lower surface 623 of the support member 600a may be positioned on the same virtual plane as the lower surface of the substrate 100. For example, the lower surface 623 of the wire protective layer 620 may be positioned on the same virtual plane as the lower surface 112 of the first substrate 110. Alternatively, the lower surface 623 of the wire protective layer 620 may be positioned on the same virtual plane as the lower surface 122 of the second substrate 120.

Therefore, when the display panel 10c is bent, the wire protective layer 620 may be concavely formed toward the connection wire 700 to have a predetermined radius of curvature (see FIGS. 17 and 18).

In addition, the entire lower surface of the substrate 100 may be etched while the support member 600a is arranged between the first substrate 110 and the second substrate 120. Therefore, the first lower edge DE1 of the first substrate 110 may include a rounded curved surface, and a groove H concavely formed may be arranged between the first lower surface 112 of the first substrate 110 and the lower surface 623 of the support member 600a. Accordingly, the first lower surface 112 of the first substrate 110 and the lower surface 623 of the support member 600a may be spaced apart from each other by the groove H. In addition, the second lower edge DE2 may include a rounded curved surface, and a groove H concavely formed may be arranged between the second lower surface 122 of the second substrate 120 and the lower surface 623 of the support member 600a. Accordingly, the second lower surface 122 of the second substrate 120 and the lower surface 623 of the support member 600a may be spaced apart from each other by the groove H. Referring to FIG. 19, at two sides of the support member 600a, the grooves H are formed between the first lower surface 112 of the first substrate 110 and the lower surface 623 of the support member 600a, and between the second lower surface 122 of the second substrate 120 and the lower surface 623 of the support member 600a, respectively, but the present disclosure is not limited thereto. Meanwhile, a number of the grooves H at two sides of the support member 600a each may be one or more, but not limited thereto.

The display device according to one or more exemplary embodiments of the present disclosure may be described as follows.

The display device according to one or more exemplary embodiments of the present disclosure may include a substrate including a first substrate and a second substrate spaced apart from each other, a support member arranged between the first substrate and the second substrate, a circuit layer arranged on the first substrate, a light-emitting element layer arranged on the circuit layer, and a connection wire arranged on the support member, and an edge of the support member may overlap the first substrate and the second substrate in a first direction along a thickness direction of the substrate.

According to one or more exemplary embodiments of the present disclosure, the support member may include a wire protective layer and a lower coating layer, and an edge of the wire protective layer may overlap the first substrate and the second substrate respectively, in the first direction.

According to one or more exemplary embodiments of the present disclosure, a material of the lower coating layer and a material of the wire protective layer may be different from each other.

According to one or more exemplary embodiments of the present disclosure, the material of the lower coating layer may have better ductility than the material of the wire protective layer.

According to one or more exemplary embodiments of the present disclosure, concave grooves may be formed between a lower-side edge of the first substrate and the lower coating layer and between a lower-side edge of the second substrate and the lower coating layer.

According to one or more exemplary embodiments of the present disclosure, the support member may include a lower coating layer that contacts a first side surface of the first substrate and a second side surface of the second substrate and a wire protective layer arranged on the lower coating layer, and the connection wire may be arranged on the wire protective layer.

According to one or more exemplary embodiments of the present disclosure, the wire protective layer may contact a part of an upper surface of the first substrate and a part of an upper surface of the second substrate.

According to one or more exemplary embodiments of the present disclosure, the display panel of the display device may further include at least one of an upper coating layer and a planarization layer arranged on the connection wire.

According to one or more exemplary embodiments of the present disclosure, a material of the lower coating layer and a material of the wire protective layer may be different from each other.

According to one or more exemplary embodiments of the present disclosure, the support member may include a lower coating layer and a wire protective layer surrounding the lower coating layer, the wire protective layer may overlap a part of an upper surface of the first substrate and a part of an upper surface of the second substrate, and the connection wire may contact the lower coating layer and the wire protective layer.

According to one or more exemplary embodiments of the present disclosure, a material of the lower coating layer and a material of the wire protective layer may be different from each other.

According to one or more exemplary embodiments of the present disclosure, the connection wire may be arranged on the lower coating layer and the wire protective layer, and a contact area between the lower coating layer and the connection wire may be greater than a contact area between the wire protective layer and the connection wire.

According to one or more exemplary embodiments of the present disclosure, the display panel of the display device may further include at least one of an upper coating layer and a planarization layer arranged on the connection wire.

According to one or more exemplary embodiments of the present disclosure, the wire protective layer may include a body part surrounding the lower coating layer and a flange part extending from the body part, and the flange part may overlap the first substrate and the second substrate.

According to one or more exemplary embodiments of the present disclosure, concave grooves may be formed between a lower-side edge of the first substrate and the body part of the wire protective layer and between a lower-side edge of the second substrate and the body part of the wire protective layer.

According to one or more exemplary embodiments of the present disclosure, the connection wire may include a first layer, a second layer arranged on the first layer, and a third layer arranged on the second layer, and a material of the first layer, a material of the second layer, and a material of the third layer may be different from one another.

According to one or more exemplary embodiments of the present disclosure, the support member may include a protrusion that protrudes further than a lower surface of the substrate.

According to one or more exemplary embodiments of the present disclosure, a thickness of a partial area of the support member may be thicker than a thickness of the substrate.

According to one or more exemplary embodiments of the present disclosure, a lower surface of the support member and a lower surface of the substrate may be positioned on the same virtual plane.

According to one or more exemplary embodiments of the present disclosure, the display panel of the display device may further include concave grooves formed between a lower-side edge of the first substrate and the support member and between a lower-side edge of the second substrate and the support member.

According to one or more exemplary embodiments of the present disclosure, the display panel of the display device may further include an insulating layer arranged between the second substrate and the connection wire.

The display device according to one or more exemplary embodiments of the present disclosure may include a substrate including a first substrate and a second substrate spaced apart from each other, a support member arranged between the first substrate and the second substrate, a circuit layer arranged on the first substrate, a light-emitting element layer arranged on the circuit layer, and a connection wire arranged on the support member, and the support member may include a protrusion that protrudes further than a lower surface of the substrate in a first direction along a thickness direction of the substrate.

According to one or more exemplary embodiments of the present disclosure, the display panel of the display device may further include concave grooves formed between a lower-side edge of the first substrate and the support member and between a lower-side edge of the second substrate and the support member.

According to one or more exemplary embodiments of the present disclosure, the support member includes a wire protective layer and a lower coating layer overlap with each other.

According to one or more exemplary embodiments of the present disclosure, the concave grooves are formed between the lower-side edge of the first substrate and the lower coating layer and between the lower-side edge of the second substrate and the lower coating layer.

According to one or more exemplary embodiments of the present disclosure, the concave grooves are formed between the lower-side edge of the first substrate and the body part of the wire protective layer and between the lower-side edge of the second substrate and the body part of the wire protective layer.

The display panel according to one or more exemplary embodiments of the present disclosure may include a substrate including a first substrate and a second substrate spaced apart from each other, a support member arranged between the first substrate and the second substrate, a circuit layer arranged on the first substrate, a light-emitting element layer arranged on the circuit layer, and a connection wire arranged on the support member, and an edge of the support member may overlap the first substrate and the second substrate in a first direction along a thickness direction of the substrate.

The display panel according to one or more exemplary embodiments of the present disclosure may include a substrate including a first substrate and a second substrate spaced apart from each other, a support member arranged between the first substrate and the second substrate, a circuit layer arranged on the first substrate, a light-emitting element layer arranged on the circuit layer, and a connection wire arranged on the support member, and the support member may include a protrusion that protrudes further than a lower surface of the substrate in a first direction along a thickness direction of the substrate.

The objects to be achieved by the present disclosure, the means for achieving the objects, and effects of the present disclosure described above do not specify essential features of the claims, and thus, the scope of the claims is not limited to the disclosure of the present disclosure.

Although the exemplary embodiments of the present disclosure have been described in more detail with reference to the accompanying drawings, the present disclosure is not limited thereto and may be embodied in many different forms without departing from the technical concept of the present disclosure. Therefore, the exemplary embodiments disclosed in the present disclosure are provided for illustrative purposes only and are not intended to limit the technical concept of the present disclosure. The scope of the technical concept of the present disclosure is not limited thereto. Therefore, it should be understood that the above-described exemplary embodiments are illustrative in all aspects and do not limit the present disclosure. scope of the claims is not limited by the disclosure, and all the technical concepts in the equivalent scope thereof should be construed as falling within the scope of the present disclosure.

LIST OF REFERENCE NUMBERS

| | | | |
|---|---|---|---|
| 10: | Display panel | 100: | Substrate |
| 110: | First substrate | 120: | Second substrate |
| 200: | Pixel array layer | 210: | Circuit layer |
| 220: | Light-emitting element layer | 300: | Encapsulation layer |
| 400: | Touch sensor layer | 500: | Color filter layer |
| 600: | Support member | 610: | Lower coating layer |
| 620: | Wire protective layer | 700: | Connection wire |
| 800: | Upper coating layer | 900: | Cover glass |
| 100: | Functional member | H: | Groove |
| P: | Protrusion | | |

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a first substrate and a second substrate spaced apart from each other;
a support member between the first substrate and the second substrate;
a circuit layer on the first substrate;
a light-emitting element layer on the circuit layer; and
a connection wire on the support member,
wherein an edge of the support member overlaps the first substrate and the second substrate in a first direction along a thickness direction of the substrate.

2. The display device of claim 1, wherein the support member includes a wire protective layer and a lower coating layer, and
wherein an edge of the wire protective layer overlaps the first substrate and the second substrate in the first direction.

3. The display device of claim 2, wherein a material of the lower coating layer and a material of the wire protective layer are different from each other.

4. The display device of claim 3, wherein the material of the lower coating layer has better ductility than the material of the wire protective layer.

5. The display device of claim 1, wherein the support member includes a lower coating layer that contacts a first side surface of the first substrate and a second side surface of the second substrate, the support member further including a wire protective layer on the lower coating layer, and
wherein the connection wire is on the wire protective layer.

6. The display device of claim 5, wherein the wire protective layer contacts a part of an upper surface of the first substrate and a part of an upper surface of the second substrate.

7. The display device of claim 5, further comprising:
at least one of an upper coating layer and a planarization layer on the connection wire.

8. The display device of claim 5, wherein a material of the lower coating layer and a material of the wire protective layer are different from each other.

9. The display device of claim 8, wherein the material of the lower coating layer has better ductility than the material of the wire protective layer.

10. The display device of claim 5, further comprising:
concave grooves between a lower-side edge of the first substrate and the lower coating layer, and between a lower-side edge of the second substrate and the lower coating layer.

11. The display device of claim 1, wherein the support member includes a lower coating layer and a wire protective layer surrounding the lower coating layer,
wherein the wire protective layer overlaps a part of an upper surface of the first substrate and a part of an upper surface of the second substrate, and
wherein the connection wire contacts the lower coating layer and the wire protective layer.

12. The display device of claim 11, wherein a material of the lower coating layer and a material of the wire protective layer are different from each other.

13. The display device of claim 11, wherein the connection wire is on the lower coating layer and the wire protective layer, and
wherein a contact area between the lower coating layer and the wire protective layer is greater than a contact area between the wire protective layer and the connection wire.

14. The display device of claim 11, further comprising:
at least one of an upper coating layer and a planarization layer on the connection wire.

15. The display device of claim 11, wherein the wire protective layer includes a body surrounding the lower coating layer and a flange extending from the body, and
wherein the flange overlaps the first substrate and the second substrate.

16. The display device of claim 15, further comprising:
concave grooves between a lower-side edge of the first substrate and the body of the wire protective layer, and between a lower-side edge of the second substrate and the body of the wire protective layer.

17. The display device of claim 1, wherein the connection wire includes a first layer, a second layer on the first layer, and a third layer on the second layer, and
wherein a material of the first layer, a material of the second layer, and a material of the third layer are different from one another.

18. The display device of claim 1, wherein the support member includes a protrusion that extends further than a lower surface of the substrate.

19. The display device of claim 1, wherein a thickness of a partial area of the support member is greater than a thickness of the substrate.

20. The display device of claim 1, wherein a lower surface of the support member and a lower surface of the substrate are on a same virtual plane.

21. The display device of claim 1, further comprising:
concave grooves formed a lower-side edge of the first substrate and the support member, and between a lower-side edge of the second substrate and the support member.

22. The display device of claim 1, further comprising:
an insulating layer between the second substrate and the connection wire.

23. A display device comprising:
a substrate including a first substrate and a second substrate spaced apart from each other;
a support member between the first substrate and the second substrate;
a circuit layer on the first substrate;
a light-emitting element layer on the circuit layer; and
a connection wire on the support member,
wherein the support member includes a protrusion that extends further than a lower surface of the substrate in a first direction along a thickness direction of the substrate.

24. The display device of claim 23, further comprising:
concave grooves between a lower-side edge of the first substrate and the support member, and between a lower-side edge of the second substrate and the support member.

25. The display device of claim 24, wherein the support member includes a wire protective layer and a lower coating layer that overlap with each other.

26. The display device of claim 25, wherein the concave grooves are between the lower-side edge of the first substrate and the lower coating layer, and between the lower-side edge of the second substrate and the lower coating layer.

27. The display device of claim 25, wherein the concave grooves are between the lower-side edge of the first substrate and a body of the wire protective layer, and between the lower-side edge of the second substrate and the body of the wire protective layer.

28. A display panel comprising:
a substrate including a first substrate and a second substrate spaced apart from each other;
a support member between the first substrate and the second substrate;
a circuit layer on the first substrate;
a light-emitting element layer on the circuit layer; and
a connection wire on the support member,
wherein an edge of the support member overlaps the first substrate and the second substrate in a first direction along a thickness direction of the substrate.
